(19) United States
(12) Patent Application Publication
(10) Pub. No.: US 2026/0056269 A1
(43) Pub. Date: Feb. 26, 2026

(54) RABI SCALAR, RAMSEY SCALAR, AND RF RABI VECTOR MAGNETOMETRY

(71) Applicant: The Regents of the University of Colorado, a body corporate, Denver, CO (US)

(72) Inventors: Christopher Kiehl, Boulder, CO (US); Thanmay Menon, Boulder, CO (US); Cindy Regal, Boulder, CO (US); Svenja Knappe, Boulder, CO (US); Tobias Thiele, Zurich (CH)

(21) Appl. No.: 18/779,896

(22) Filed: Jul. 22, 2024

Related U.S. Application Data
(60) Provisional application No. 63/528,324, filed on Jul. 21, 2023.

(51) Int. Cl. G01R 33/26

(52) U.S. Cl. CPC G01R 33/26

(57) ABSTRACT

A method for atomic scalar magnetometry can include: (i) applying optical pumping to a vapor within a vapor cell; (ii) ramping off a pump power of the optical pumping over a time period; (iii) driving Rabi oscillations in the vapor by applying a microwave pulse sequence to the vapor, and (iv) determining a magnetic field strength by measuring frequency of the Rabi oscillations.

### CROSS-REFERENCE TO RELATED APPLICATIONS

This application claims priority to U.S. Provisional Application No. 63/528,324, filed on Jul. 21, 2023, and entitled “RABI SCALAR, RAMSEY SCALAR, AND RF RABI VECTOR MAGNETOMETRY”, the entirety of which is incorporated herein by reference for all purposes.

### STATEMENT REGARDING GOVERNMENT RIGHTS

This invention was made with government support under grant number W911NF-21-1-0127, awarded by the U.S. Army research Office, grant number W911NF-19-1-0330, awarded by the U.S. Army research Office, grant number PHY1734006, awarded by the National Science Foundation, grant number N00014-17-1-2245, awarded by the Office of Naval Research, and grant number 2016244, awarded by the National Science Foundation. The government has certain rights in the invention.

### BACKGROUND

Optically pumped magnetometers (OPMs) are state-of-the-art sensors that can reach sensitivities below 1 fT/\sqrt{Hz}, enable precise detection of biomagnetic signals, and push the boundaries for scientific exploration by aiding in searches for permanent electron dipole moments and dark matter. Applications of OPMs in geomagnetic fields such as navigation, geophysics, space, and unexploded ordinance detection have to take into account systematics that depend on the orientation of the sensor with respect to the magnetic field known as heading errors. For alkali-metal OPMs, this heading error is on the order of 10 nT and manifests from unresolved frequency components in the magnetometer signal that are attributed to nonlinear Zeeman (NLZ) shifts and the different gyromagnetic ratios of the ground hyperfine manifolds.

Only in regimes of narrow magnetic resonances and high spin polarization can this heading error be accurately modeled to 0.1 nT. In practice, these regimes often become intangible due to line broadening from atomic collisions and the challenges associated with implementing fast, high-fidelity optical pumping using modest pump powers in arbitrarily oriented magnetic fields. Various other approaches have been developed to mitigate heading error including spin locking, light polarization modulation, double-modulated synchronous pumping, and leveraging tensor lightshifts, but all these approaches neglect frequency shifts arising from the different Zeeman resonances between the F=I±½ manifolds and have their own practical challenges. Furthermore, methods that utilize higher-order polarization moments are not feasible in compact OPM packages with high buffer gas pressures.

Furthermore, state-of-the-art atomic vector magnetometers utilize a 3D coil system to extract full vector information by employing low-frequency coil modulations (<20 Hz) and detecting the corresponding sidebands in total field (|\vec{B}|) measurements. At geomagnetic fields, the sensitivity of these sidebands are limited to the 1 nT/\sqrt{Hz} level, likely due to the fact that the coil modulation amplitude is limited to small currents due to power constraints. In order to achieve vector accuracies at the 10 μrad level, sensor rotations are required to calibrate coil system non-orthogonalities and coil scaling factors. Careful measurements of thermal coefficients are taken to maintain calibration accuracy. Accuracy from drifts could be further improved with in-situ calibrations, but the complexity of incorporating sensor rotations makes this intangible.

The subject matter claimed herein is not limited to embodiments that solve any challenges or that operate only in environments such as those described above. Rather, this background is only provided to illustrate one exemplary technology area where some embodiments described herein may be practiced.

### SUMMARY

At least some disclosed embodiments relate to Rabi scalar magnetometry. An approach to atomic scalar magnetometry is disclosed where resonances of multiple hyperfine transitions are measured using Rabi oscillations driven by a microwave field (e.g., about 6.8 GHz). By measuring the resonance of at least two hyperfine transitions of an alkali atom (e.g., Rb 87), the vapor cell pressure shift caused by a buffer gas such as diatomic nitrogen and the magnetic field strength can be extracted. A fitting algorithm is disclosed that can eliminate systematics due to AC Stark shifts and nonlinear Zeeman shifts when extracting these resonant frequencies. This fitting algorithm uses the extensive information contained in the Rabi oscillation frequencies driven at multiple microwave detunings with a physical model to correct these systematics. Disclosed embodiments can be implemented to eliminate heading errors in atomic magnetometers.

The resonance frequencies deduced from microwave-driven Rabi oscillations are very sensitive to AC Stark shifts that normally cause large inaccuracies. The disclosed fitting algorithm does a remarkable job at correcting these systematics. By applying the disclosed principles, it has been found that the magnetic field can be extracted with an accuracy below a few hundred picotesla.

A key objective of many applications, like magnetic navigation, is determining the magnetic field scalar value accurately. All atomic magnetometers have systematics of the scalar field that depend on the orientation of the magnetometer to the field directions. These heading errors arise due to uncertainty in the atomic state prepared by optical pumping. These systematics are called heading-errors. They are on the order of a few nanotesla. By using the resonance of hyperfine transitions extracted accurately with Rabi measurements, disclosed implementations can be insensitive to these heading-errors. The disclosed techniques can be used to create a lookup table of the heading error for a traditional atomic magnetometer, or can be implemented on-sensor for real-time heading error correction.

At least some disclosed embodiments are directed to Ramsey scalar magnetometry. An approach to atomic scalar magnetometry is disclosed where Ramsey interferometry is performed using a microwave field (e.g., about 6.8 GHz) on multiple hyperfine transitions of an alkali species atom (e.g., Rb 87). By performing Ramsey interferometry to extract the resonant microwave frequency for at least two hyperfine transitions, the vapor cell pressure shift caused by a buffer gas (e.g., diatomic nitrogen) and the magnetic field strength can be extracted. It has been found that a Ramsey interferometry protocol with the disclosed approach is very insensitive to systematics caused by the microwave field. Disclosed embodiments thus have the potential to eliminate heading errors in atomic magnetometers.

As disclosed herein, Ramsey interferometry can be used on multiple transitions to extract an accurate measurement of the magnetic field. Ramsey interferometry has not been done on multiple transitions that are each sensitive to the magnetic field. Disclosed embodiments can utilize a pi/2 3pi/2 Ramsey sequence (or Ramsey interferometry protocol), which has been shown to be less sensitive to systematics from off-resonant microwave driving. Disclosed techniques can involve purposely varying the microwave detuning from a given hyperfine transition and measuring the Ramsey oscillation frequency for each microwave detuning. By fitting a linear line to these Ramsey oscillation frequencies at different microwave detunings, the microwave resonance can be extracted. It has been found that the disclosed Ramsey protocol is remarkably insensitive to systematics.

There are a wide range of applications for atomic scalar magnetometers in geomagnetic fields including archeological mapping, fundamental physics experiments, mineral exploration, magnetic navigation, space magnetometry, and/or others. By using the resonance of hyperfine transitions with Ramsey interferometry, disclosed techniques can be insensitive to these systematics and can measure the magnetic field scalar value with a significantly reduced heading error (e.g., below a few 100 picotesla). The disclosed techniques can be used to create a lookup table of the heading error for a traditional atomic magnetometer, or can be implemented on-sensor for real-time heading error correction.

At least some disclosed embodiments are directed to RF Rabi vector magnetometry. Disclosed is an approach to atomic vector magnetometry that involves referencing an unknown magnetic field to a set of radiofrequency (RF) polarization ellipses. The atomic sensor can be a vapor cell filled with an alkali species (e.g., Rb 87). In the presence of an unknown magnetic field, the ground state Zeeman sublevels split. If the frequency of the RF electromagnetic field is near the Zeeman splitting (e.g., about 350 kHz), it drives coherent Rabi oscillations between the Zeeman sublevels. If this vapor cell is placed within a 3D coil system, arbitrary RF fields can be generated. By varying the RF strength in different coil pairs, the coil system and RF polarization ellipses can be calibrated. The frequency of these Rabi oscillations is determined by the RF polarization ellipse and the direction of the external magnetic field. Thus, after calibration, the unknown magnetic field vector can be extracted from the Rabi frequencies driven by the RF fields.

Existing atomic magnetometers that use RF fields do not use Rabi oscillations to extract vector information. Instead, under conventional approaches, the RF field is used to determine the Zeeman splitting to extract the magnetic field strength. A common technique for atomic magnetometers to extract the full magnetic field vector is by applying a rotating DC magnetic field via a coil system, or rotating the whole apparatus itself.

Utilizing RF fields in combination with Rabi oscillations can present various advantages. For instance, The microwave Rabi oscillations between hyperfine ground states have worse coherence time compared to RF Rabi oscillations between Zeeman sublevels, meaning that the RF Rabi magnetometer can achieve improved sensitivity. With only a single optical axis, the RF Rabi magnetometer can have zero dead-zones (directions where the magnetic field cannot be detected), whereas a microwave Rabi magnetometer may inherently have dead-zones.

Under conventional approaches, many sensitive and accurate atomic vector magnetometers use a coil system as a vector reference. From current modulations in this coil system while making scalar measurements, complete vector information is extracted. These vector magnetometers require calibrations to overcome coil system drifts and machining tolerances that limit the directional accuracy. Typically rotating the whole apparatus is used to calibrate the coil system, which significantly complicates the sensor design and limits the calibration speed. Furthermore, the coil modulations used are low frequency (e.g., within the 10 Hz range) and the sensitivity is limited by 1/f electronic noise.

In contrast, as disclosed herein, by exciting RF fields between different coil pairs, the coil system, and the RF fields produced, can be quickly calibrated on the 20 ms time-scale (much faster than methods that rotate the whole sensor within a coil system). Thus, by not requiring physical rotations, the disclosed RF magnetometer can enable a simpler design, which may benefit applications that require lower SWaP (size, weight, and power). Furthermore, since the Rabi frequencies measured are in the 10-100 kHz range, 1/f noise can be significantly reduced to improve sensitivity.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

Additional features and advantages will be set forth in the description which follows, and in part will be obvious from the description, or may be learned by the practice of the teachings herein. Features and advantages of the invention may be realized and obtained by means of the instruments and combinations particularly pointed out in the appended claims. Features of the present invention will become more fully apparent from the following description and appended claims, or may be learned by the practice of the invention as set forth hereinafter.

### BRIEF DESCRIPTION OF THE DRAWINGS

In order to describe the manner in which the above-recited and other advantages and features can be obtained, a more particular description of the subject matter briefly described above will be rendered by reference to specific embodiments which are illustrated in the appended drawings. Understanding that these drawings depict only typical embodiments and are not therefore to be considered to be limiting in scope, embodiments will be described and explained with additional specificity and detail through the use of the accompanying drawings in which:

FIG. 1 conceptually depicts microwave resonances for Rb 87.

FIG. 2 depicts an example magnetometer configuration for implementing Rabi and/or Ramsey scalar magnetometry.

FIGS. 3 and 4 illustrate example Rabi and Ramsey pulse sequences for performing atomic scalar magnetometry.

FIG. 5 illustrates the Fourier transform of an FSP signal measured in the regime of low-polarization pumping.

FIG. 6 depicts the fitting of Rabi resonances to the Breit-Rabi formula to extract the magnetic field value.

FIGS. 7-9 depict polar angle dependence of Rabi frequencies for various hyperfine transitions.

FIG. 10 depicts fitted polarization ellipses.

FIG. 11 depicts example Rabi oscillations throughout a pulse sequence.

FIG. 12 provides another depiction of fitting Rabi resonances to extract the magnetic field value.

FIG. 13 depicts Ramsey frequency vs microwave detuning for a hyperfine transition.

FIG. 14 depicts residuals of fitting the Breit-Rabi formula to the hyperfine resonances measured with Ramsey interferometry.

FIGS. 15A, 15B, and 15C depict a comparison of FSP heading errors measured by Rabi and Ramsey scalar magnetometry.

FIG. 16 illustrates hyperfine ground states for Rb 87, wherein spherical RF components may drive Rabi oscillations.

FIG. 17 illustrates a conceptual representation of spherical RF components determined by a DC magnetic field.

FIG. 18 illustrates another conceptual representation of spherical RF components with non-orthogonal axes.

FIG. 19 depicts a heat map of measured RF Rabi frequency as a function of magnetic field direction using a single RF coil, as well as a graph of measured RF Rabi oscillation with single coil excitation for a particular RF Rabi frequency and magnetic field direction.

FIGS. 20A and 20B depict additional graphs showing Rabi oscillations for magnetic fields and Rabi frequencies.

FIG. 21 illustrates an example 3D RF coil system positioned about a microfabricated vapor cell.

FIGS. 22, 23, and 24 illustrate example flow diagrams depicting acts associated with implementations of the subject matter described herein.

FIG. 25 illustrates an example system that may comprise or implement one or more disclosed embodiments.

### DETAILED DESCRIPTION

Disclosed embodiments are directed to systems, methods, devices, and/or techniques related to Rabi scalar magnetometry, Ramsey scalar magnetometry, and RF Rabi vector magnetometry.

### Rabi Scalar and Ramsey Scalar Magnetometry

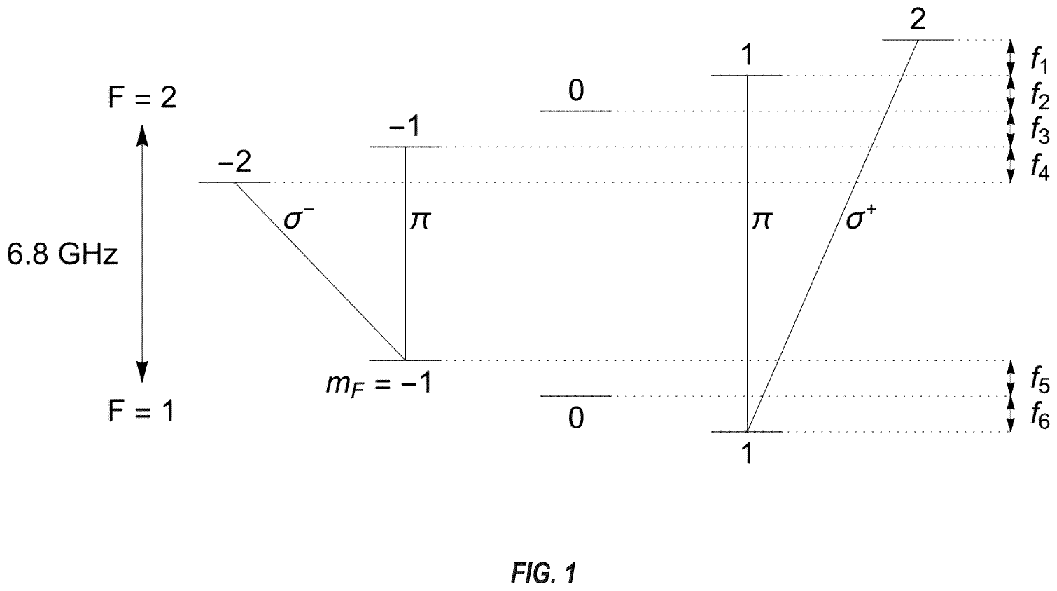

Disclosed embodiments are directed to performing accurate scalar magnetometry by using Ramsey and Rabi spectroscopy as two independent methods of detecting microwave resonances between hyperfine ground manifolds to directly measure the heading error of an OPM based on free spin precession (FSP). FIG. 1 conceptually depicts an energy level diagram for Rb 87 showing these microwave resonances (i.e., the four hyperfine transitions used for Ramsey interferometry and Rabi spectroscopy). Zeeman splittings are labeled in FIG. 1 as fᵢ, which contribute to the Larmor FSP signal. These microwave resonances are driven between unique pairs of Zeeman sublevels, where non-linear Zeeman (NLZ) splittings are accurately accounted for using the Breit-Rabi formula, and thus do not suffer from usual heading error mechanisms. By employing quantum nondemolition sensing based on Faraday rotation to track spin dynamics in real-time, the Rabi method can enable faster readout compared to the time required to execute several pulse sequences in the Ramsey interferometry protocol. Meanwhile, Ramsey interrogation can be inherently less sensitive to frequency shifts by using short microwave pulses. Importantly, both of these methods can facilitate the practical advantage of operating in high buffer gas pressures utilized in microfabricated vapor cells.

Compared to vapor cell atomic clocks that employ linearly-polarized microwave sources along a well-defined magnetic field to minimize Ramsey pulling systematics, this disclosed approaches face the challenge of managing off-resonant driving while operating in arbitrary magnetic field directions. The disclosed techniques can overcome this obstacle by (1) utilizing adiabatic power ramps during optical pumping to suppress Larmor precession that would otherwise degrade the Rabi and Ramsey signals, (2) incorporating microwave polarization ellipse (MPE) calibrations within a complete model to accurately account for the atom-microwave coupling during Rabi oscillations, and (3) employing a π/2-T_{R}-3π/2 hyper-Ramsey sequence and sweeping both the free evolution time (T_{R}) and the microwave detuning in the disclosed Ramsey protocol to mitigate frequency shifts from off-resonant driving. The disclosed techniques have demonstrated heading error agreement to within 0.6 nT by comparing these two methods to FSP measurements over a range of magnetic field directions at 50 μT. This result is consistent with estimates of 0.5 nT and 0.1 nT systematic errors for the Rabi and Ramsey methods respectively based on theoretical simulations, as well as technical drifts in the optical pumping.

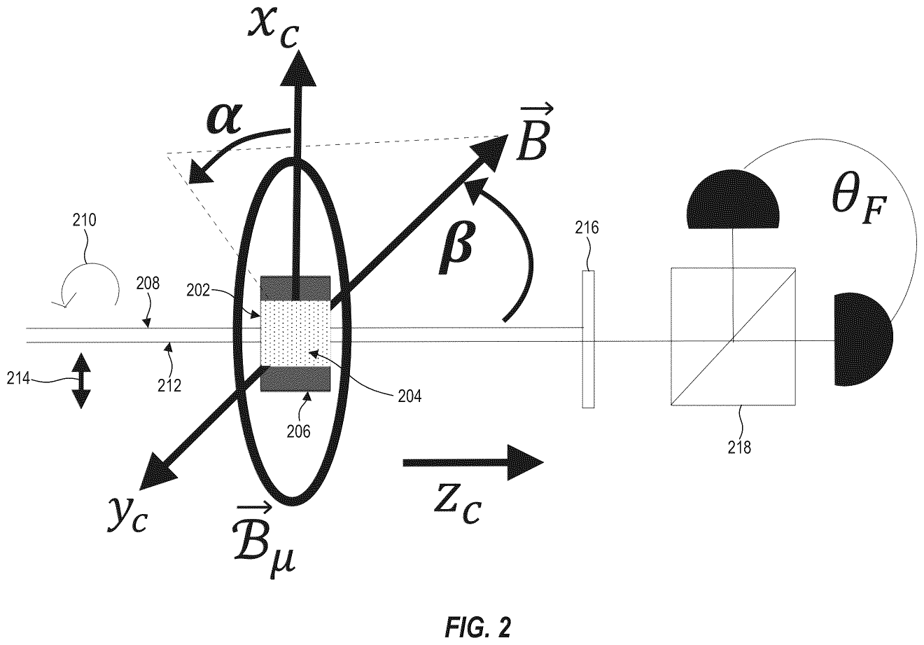

FIG. 2 depicts an example magnetometer configuration for implementing Rabi and/or Ramsey scalar magnetometry, as disclosed herein. FIG. 2 illustrates a vapor cell 202 containing a vapor 204 (e.g., an alkali atom vapor). The vapor cell 202 can be heated, and filled with a buffer gas. In an illustrative example described herein, For instance, the vapor cell 202 comprises a 3×3×2 mm\hat{ }3 microfabricated vapor cell with a single optical axis, and the vapor cell 202 is heated to 100° C. and is filled with Rb 87 vapor and 180 Torr of N2 buffer gas. At this buffer gas pressure, Rb—N2 collisions broaden the optical D1 and D2 transitions to 6 GHz.

As shown in FIG. 2, the vapor cell 202 is contained within a rectangular microwave cavity 206 that is the source for driving hyperfine transitions. A 3D coil system defines an orthogonal coordinate system (x, y, z), where a scalar calibration corrects for non-orthogonal misalignments between the coil pairs. In the illustrative example noted above, the coil system generates a programmable 50 μT magnetic field \vec{B} (labeled in FIG. 2), whose orientation is defined by azimuthal and polar angles α and β respectively (also labeled in FIG. 2).

FIG. 2 conceptually depicts polarized pump light 208 for applying optical pumping to the vapor 204 within the vapor cell 202 (with the polarization of the pump light 208 indicated in FIG. 2 by arrow 210). In the illustrative example noted above, to initiate spin precession, the pump light 208 comprises at least a 100 μs pulse at 400 mW of 795 nm elliptically polarized pump light that is tuned within a few GHz of the D1 line, which polarizes atomic spin along the pump beam. In the illustrative example, a large pump power is chosen to saturate the atoms and minimize effects from drifts in the pump detuning and power.

FIG. 2 also conceptually depicts a probe beam 212 for acquiring a measurement signal (or simply “signal”), which can indicate free spin precession (FSP) data (and/or other data, such as frequency and/or other characteristics of Rabi and/or Ramsey oscillations) associated with the vapor 204 within the vapor cell 202. The probe beam 212 can comprise linearly polarized (or near-linearly polarized) light (with the polarization of the probe beam 212 indicated in FIG. 2 by arrow 214) and can be detected via a dichroic mirror 216 and a polarized beam splitter 218 to obtain the measurement signal. Rabi and/or Ramsey oscillations can be derived from the measurement signal. In the illustrative example noted above, spin dynamics (indicated by the FSP data/signal) can be detected through the Faraday rotation (denoted in FIG. 2 as OF) of a 1 mW linearly polarized probe beam 212 that is 170 GHz blue-detuned from the D2 line. In some implementations, both the pumping light and the probe light are achieved with collinear light beams. In some instances, the same light source (e.g., the same laser) generates or provides both the pumping light and the probing light.

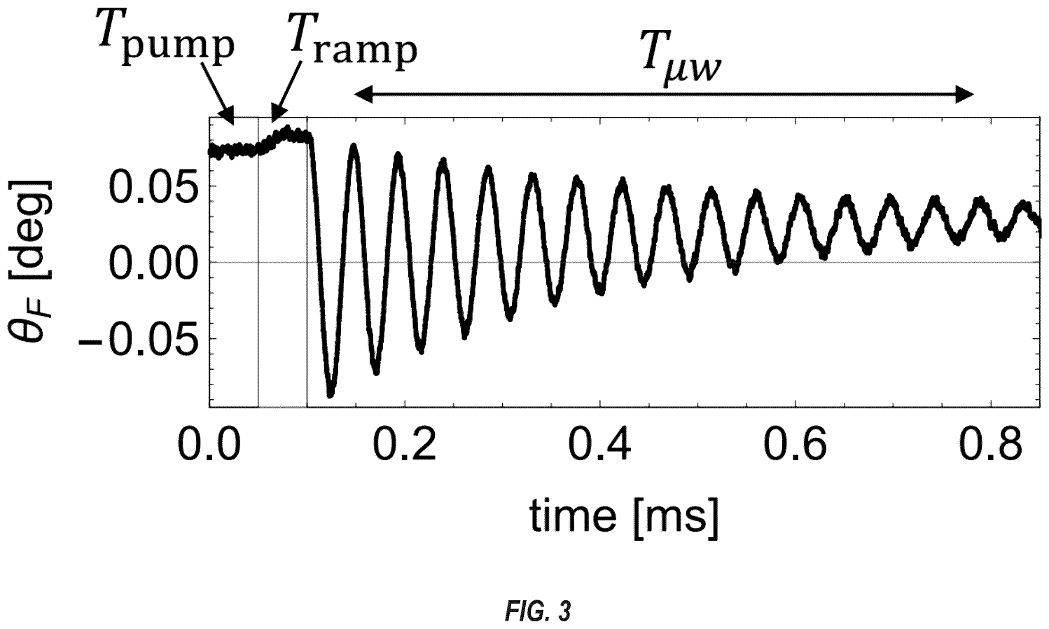

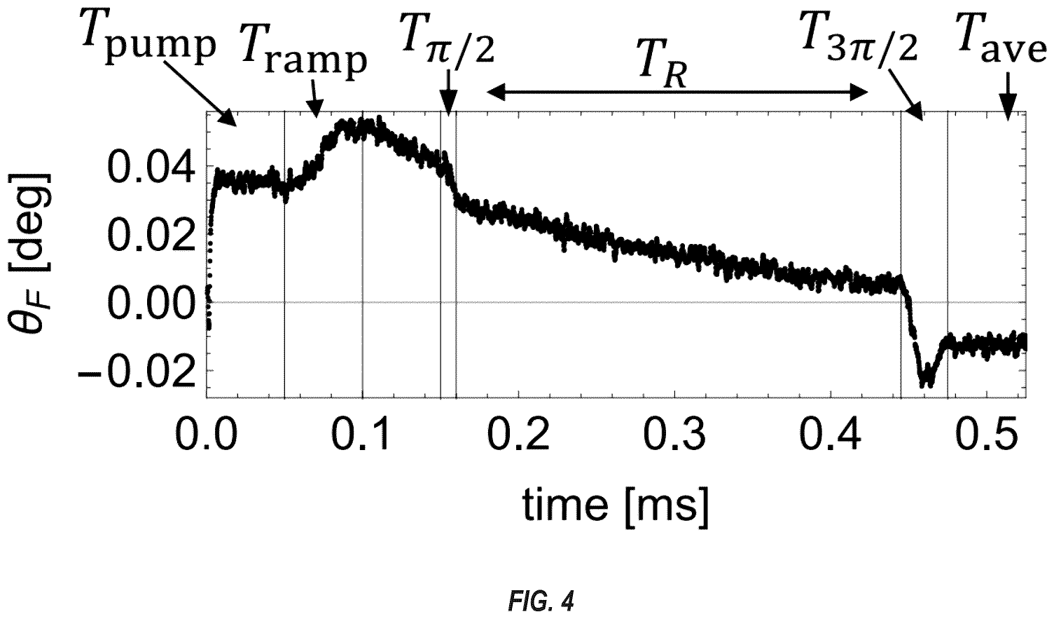

In the illustrative example heretofore described, for the Rabi and Ramsey schemes disclosed herein, the atomic ensemble (e.g., the vapor 204 within the vapor cell 202 and rectangular microwave cavity 206) is pumped with the pump light 208 for 50 μs at 60 mW, and then the pump power is linearly or monotonically ramped off over the next 50 μs. FIGS. 3 and 4 illustrate the Rabi and Ramsey pulse sequences noted above, respectively. In at least some instances, the linear ramping of the pump power suppresses Larmor precession by orienting the atomic spins along the magnetic field B by adiabatically following the effective field produced by B and the pump vector light shift. In the illustrative example noted above, the adiabatic pump ramp is either followed by a 0.85 ms microwave pulse to drive Rabi oscillations, or by the Ramsey pulse sequence (described in more detail hereinafter).

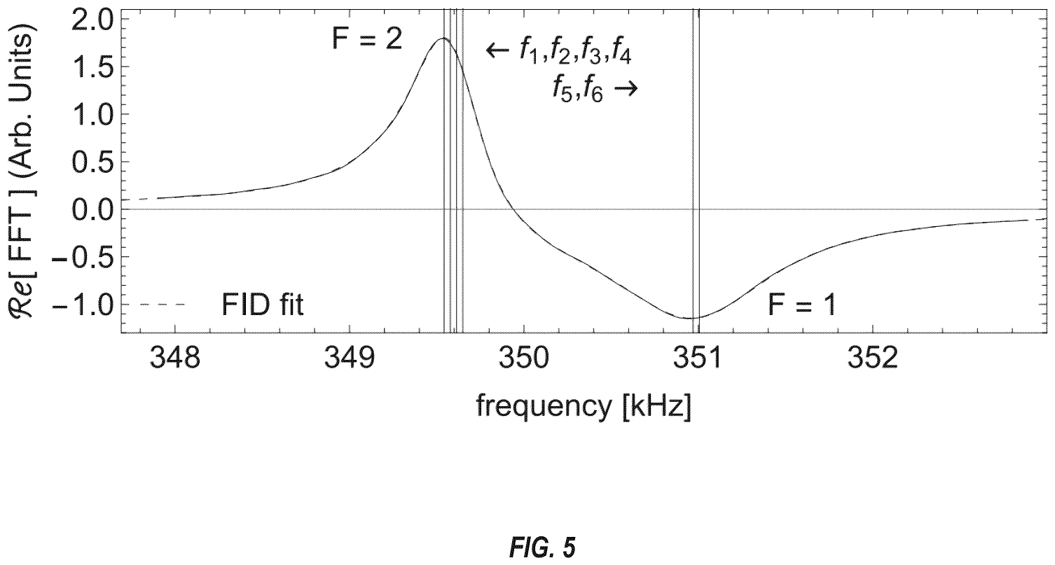

The disclosed principles can be applied to achieve heading error correction for FSP signals with low atomic spin polarization where no accurate physical models for heading errors exist. In this low spin polarization regime, the FSP spectrum consists of both F=1 and F=2 Zeeman resonances that are separated at 50 μT by 1.4 kHz. FIG. 5 illustrates the Fourier transform of an FSP signal measured in the regime of low-polarization pumping where both F=1 and F=2 precession frequencies are present. Systematics can arise due to the uncertainty in the amplitudes and relative phases of the nonlinear Zeeman frequencies (indicated in FIG. 5 with vertical lines) that are not accounted for in the fitting model.

The NLZ effect splits the Zeeman resonances noted above into frequency components {f₁, . . . , f₆} separated by 36 Hz. The FSP spectrum can be modeled as two resonances f_{L,j}(B)≈μ_{B}(gₛ−gᵢ±4gᵢ)B/4h that is the mean Zeeman splitting for the F=1+½ manifolds, where/=3/2 is the nuclear spin, gₛ and gᵢ are the electronic and nuclear Lande g-factors, h is Planck's constant, μ_{B} is the Bohr magneton, and B is the magnetic field strength. For the real component of the FSP signal's Fourier transform, this model is given by

$${\sum }_{j = 1 , 2} {a}_{j} \frac{Cos [ {ϕ}_{j} ] - Sin [ {ϕ}_{j} ] ( f - {f}_{L , j} )}{{( f - {f}_{L , j} )}^{2} + {w}_{j}^{2} / 4} \qquad ( 1 )$$

where ϕ=2πf_{L,j}t₀±ϕ/2 are phase shifts due to a starting time offset to with ϕ as a relative phase between the I±½ resonances respectively. Here the strength and broadening of this signal is given by amplitudes a_{1,2} and linewidths w_{1,2}≈1 kHz. Based on the initial atomic state and the direction of \vec{B}, heading error arises in this model from the unresolved NLZ frequency components that bias the observed resonances from f_{L,j}.

To bypass this heading error, atom-microwave coupling may be harnessed to detect resonances

$${v}_{m}^{{m}^{′}} \approx 6.8 GHz$$

between hypertine sublevels |1, m [symbol] and |2, m′ [symbol] that is given by

$$\frac{{hv}_{m}^{{m}^{′}}}{Δ E} = \frac{{m}^{′} - m}{{g}_{s} / {g}_{i} - 1} + {\sum }_{M = m , {m}^{′}} \sqrt{1 + \frac{4 M}{2 I + 1} + {x}^{2}} \qquad ( 2 )$$

where x=(gₛ−gᵢ)μ_{B}B/ΔE and ΔE=(A+hv_{pg}/2) (1+½) is the hyperfine splitting expressed in terms of the magnetic dipole hyperfine constant A and the pressure shift arising from N₂ buffer gas collisions v_{bg}≈88 kHz. At a microwave frequency ν_{μ}, the atom-microwave coupling Hamiltonian H is quantified under the rotating-wave approximation (RWA) as

$$H = [ ( A + h \frac{{v}_{bg}}{2} ) S \cdot I + {μ}_{B} ( {g}_{s} {S}_{z} + {g}_{i} {I}_{z} ) B ] {†}^{} - 1 {hv}_{μ} + h {\sum }_{m , {m}^{′}} [ \vert \overline{1 , m} 〉 {Ω}_{m}^{{m}^{′}} 〈 \overline{2 , {m}^{′}} \vert + h . c . ] \qquad ( 3 )$$

where, in order to preserve NLZ effects during the RWA, a modified hyperfine basis |F̅,̅ m̅ [symbol] = [symbol] |F, m [symbol] is implemented with [symbol] defined as the operator that diagonalizes the hyperfine and Zeeman terms in the first line of Equation (3).

The Rabi frequency Ωₘ^{m}′ is given by

$${Ω}_{m}^{{m}^{′}} = \frac{{μ}_{B} 〈 \overline{1 , m} \vert ( {g}_{s} {S}_{k} + {g}_{i} {I}_{k} ) {k}_{( a , β )}^{} {†}^{} \vert \overline{2 , {m}^{′}} 〉}{2 h} \qquad ( 4 )$$

where k=±,π denotes the polarization of the hyperfine transition and S_{π}=S_{z} and S_{±}=Sₓ+iS_{y} are the raising and lowering electron spin operators with analogous definitions for the nuclear spin operators Iₖ. The MPE vector

$${k}_{( a , β )}^{} = {R}_{z} ( α ) {R}_{y} ( β ) \{ {x}_{} {e}^{i {ϕ}_{x}} , {y}_{} {e}^{i {ϕ}_{y}} , {z}_{} \} \cdot {\hat{ϵ}}_{k} \qquad ( 5 )$$

is projected onto the spherical basis ∈_{±}={∓1, ±i, 0} and ∈_{π}={0,0,1} and contains the three microwave amplitudes ( [symbol] ₓ, [symbol] _{y}, [symbol] _{z}) and two relative phases (ϕₓ, ϕ_{y}) that fully-define any MPE. To account for different magnetic field directions, the 3D rotation operators R_{y,z} rotate the MPE vector. In this framework, without loss of generality, the magnetic field \vec{B} can be regarded as pointing along z.

In Rabi scalar magnetometry, Rabi oscillations are driven between sublevels |1, m [symbol] and |2, m′ [symbol] with microwave detunings

$${Δ}_{m}^{{m}^{′}} = {v}_{μ} - {v}_{m}^{{m}^{′}}$$

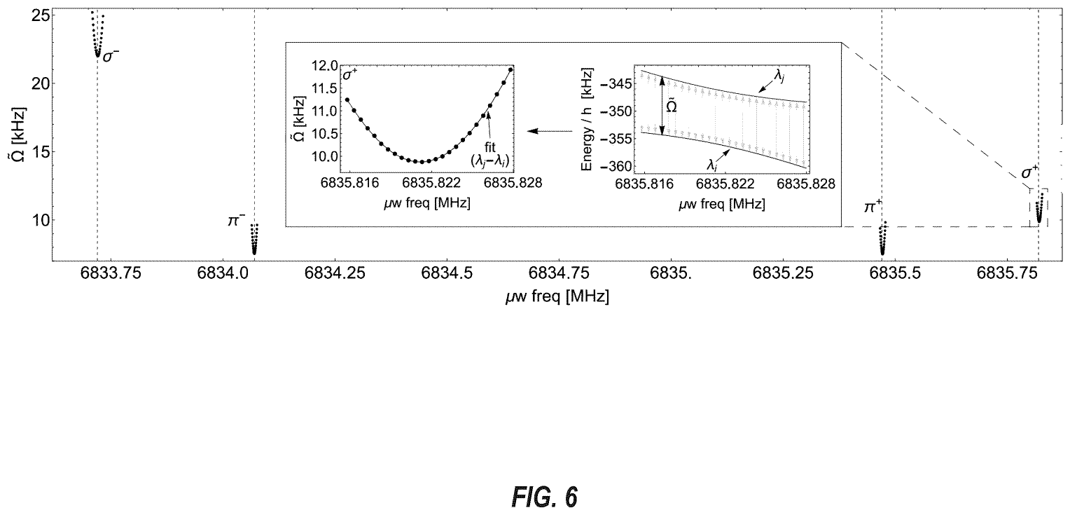

about the four σ⁺, π⁺, n⁻, and σ⁻ hyperfine transitions. FIG. 6 depicts the fitting of Rabi resonances to the Breit-Rabi formula to extract the magnetic field value. The inset graphs of FIG. 6 show a fit of the σ⁺ transition for PE2 using the eigenstates of the atom-microwave Hamiltonian. The generalized Rabi frequencies

$${\tilde{Ω}}_{m}^{{m}^{′}}$$

can be extracted by fitting to the Rabi oscillation signals using the following time-domain model

$${θ}_{F} ( t ) = {a}_{0} + {a}_{1} {e}^{- t / {t}_{1}} + {a}_{2} {e}^{- t / {t}_{2}} + {e}^{- t / {t}_{3}} ( {a}_{3} Sin [ 2 π tf ] + {a}_{4} Cos [ 2 π tf ] ) \qquad ( 6 )$$

where the two DC-offset decay constants t₁ and t₂ are required to account for the atomic population redistribution arising from spin-exchange collisions. While the frequency

$${\tilde{Ω}}_{m}^{{m}^{′}}$$

of these Rabi oscillations can be well-approximated as

$${( {\tilde{Ω}}_{m}^{{m}^{′}} )}^{2} \approx {( {Δ}_{m}^{{m}^{′}} )}^{2} + {\vert {\tilde{Ω}}_{m}^{{m}^{′}} \vert}^{2} when \vert {\tilde{Ω}}_{m}^{{m}^{′}} \vert ≪ {Δ}_{m}^{{m}^{′}} ,$$

the exact generalized Rabi frequency can be given by

$${\tilde{Ω}}_{m}^{{m}^{′}} = {λ}_{j} - {λ}_{i} ,$$

where λⱼ and λᵢ are the eigenvalues of Equation (3) that correspond to the pair of dressed states coupled by the microwave field. Using this exact model, generalized Rabi frequencies

$${\tilde{Ω}}_{m}^{{m}^{′}}$$

can be measured at 25 microwave detunings separated by 800 Hz about each of four hyperfine transitions and fit unique values for the Rabi rates

$$\vert {Ω}_{m}^{{m}^{′}} \vert ,$$

the pressure shift v_{bg}, and the magnetic field strength B. Importantly, these measurements can be taken in random order to minimize effects from microwave power drifts.

During these fits, the complex phases

$$Arg ( {Ω}_{m}^{{m}^{′}} )$$

are calculated from an MPE calibration that specifies the MPE vector [symbol] ^{(α,β)} in Equation (3). To account for dependence of [symbol] ^{(α,β)} on the microwave frequency that arises from the lineshape of the microwave cavity modes, four separate MPE calibrations can be performed corresponding to a microwave frequency that is near-resonant with each hyperfine transition, such as v*∈{6833.72, 6834.07, 6835.47, 6835.82} MHz. To make these calibrations, the corresponding generalized Rabi frequency

$${\tilde{Ω}}_{m}^{{m}^{′}}$$

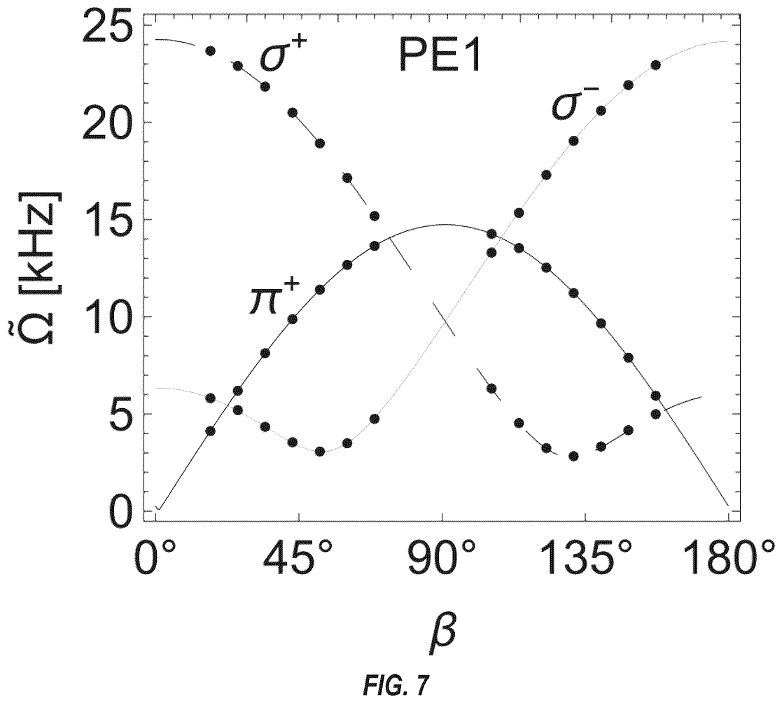

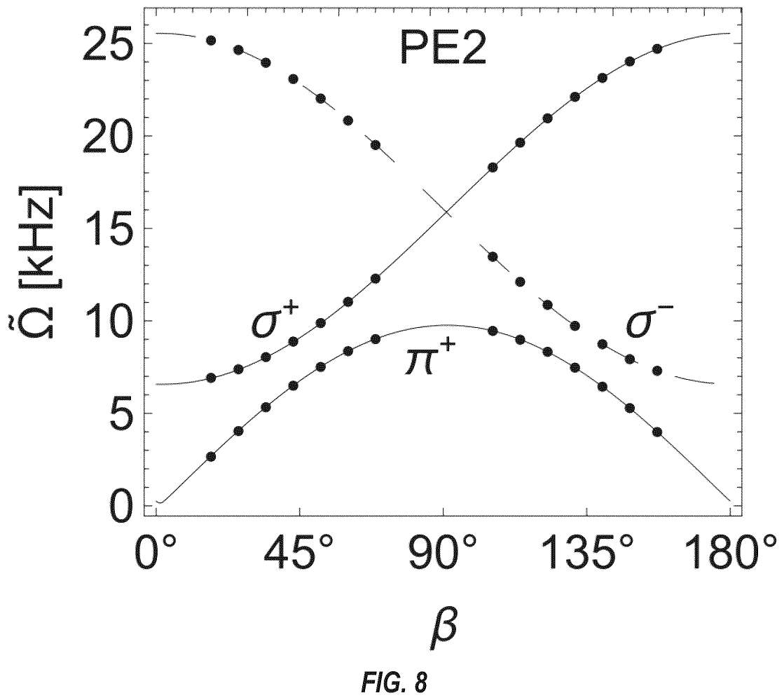

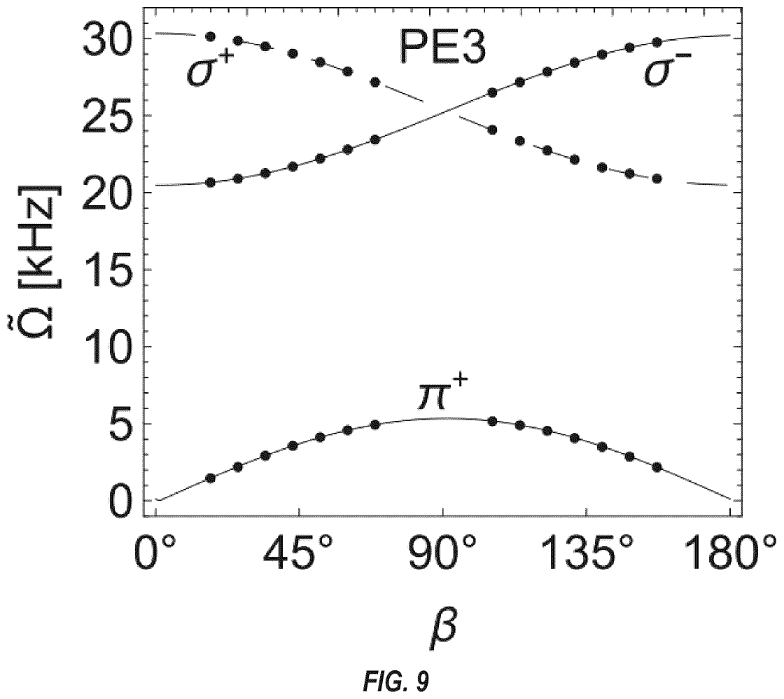

can be measured at 14 polar angles (β), and can be fit for each v*, the free 5 MPE parameters ( [symbol] ₓ, [symbol] _{y}, [symbol] ₂, ϕₓ>ϕ_{y}), and pressure shift v_{bg} using the eigenvalues of Equation (3). FIGS. 7-9 depict polar angle dependence of the measured Rabi frequencies for the σ⁺, n⁺, and σ⁻ hyperfine transitions. The solid lines show fits to calibrate the polarization ellipses. During the calibrations, B-values extracted from FSP fits can be used with negligible effect of the calibration accuracy since

$${\tilde{Ω}}_{m}^{{m}^{′}}$$

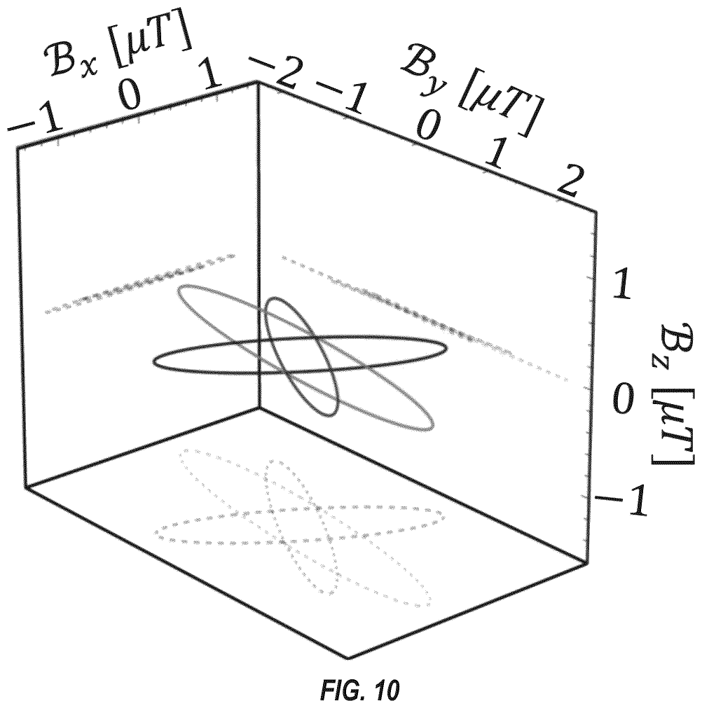

depends on the Zeeman shift to second-order near the transition-resonance. To monitor that systematics are properly accounted for, independent measurements can be made with multiple MPEs (e.g., three, or a different quantity). FIG. 10 illustrates thee fitted polarization ellipses.

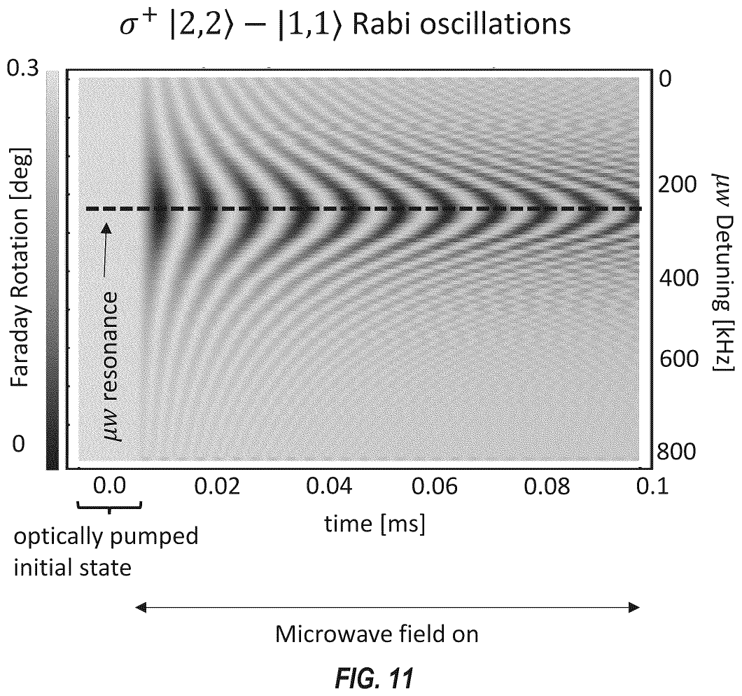

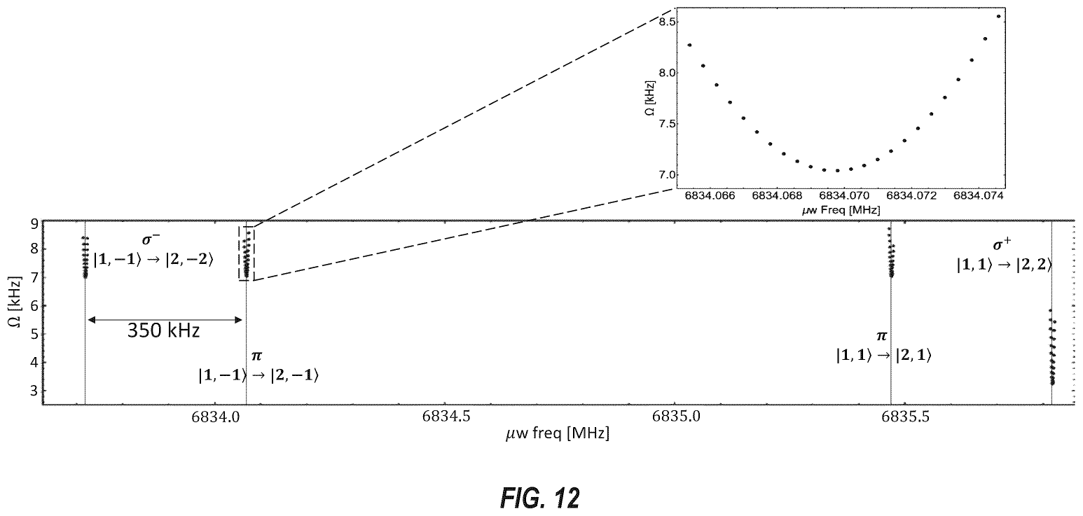

FIG. 11 depicts example Rabi oscillations for σ⁺|2,2 [symbol] −|1,1 [symbol] throughout a pulse sequence. FIG. 12 provides another depiction of fitting Rabi resonances to extract the magnetic field value. In some instances, the filtering algorithm utilizes a full atomic-microwave coupled Hamiltonian that assumes a rotating wave approximation, uses the calibrated polarization ellipse of the microwave field to account for complex Rabi frequencies (e.g., real and imaginary components), and includes polarization ellipse frequency-dependence, such as

$$H ( t ) = ( {A}_{h f s} + {δ}_{h f s} ) I \cdot S + {μ}_{B} ( {g}_{s} S + {g}_{1} I ) \cdot ( {B}_{d c} \hat{z} + {μ w}^{} ( t ) ) \qquad ( 7 )$$

where δ_{hfs} represents the pressure shift, B_{dc} represents Δ_{zeeman}, and [symbol] ^{μw} represents

$${Δ}_{Stark}^{μ w} .$$

The disclosed Ramsey scalar magnetometry protocol extracts magnetic field strength by directly measuring the transition frequencies

$${v}_{m}^{{m}^{′}}$$

of the σ^{±} and π^{±} hyperfine transitions. In some implementations, a π/2−T_{R}−3π/2 hyper-Ramsey pulse sequence is used with

$${t}_{π / 2} = 4 / \vert {\tilde{Ω}}_{m}^{{m}^{′}} \vert \approx 10 μs$$

(see FIG. 4). In some instances, because the Rabi rates

$$\vert {\tilde{Ω}}_{m}^{{m}^{′}} \vert$$

vary win magnetic field direction (see FIGS. 7-9), microwave powers can be selected for each hyperfine transition such that

$$\vert {Ω}_{m}^{{m}^{′}} \vert \approx 25 kHz .$$

After each pulse sequence, the resulting Faraday signal can be averaged for 50 μs to filter out residual 350 kHz Larmor precession.

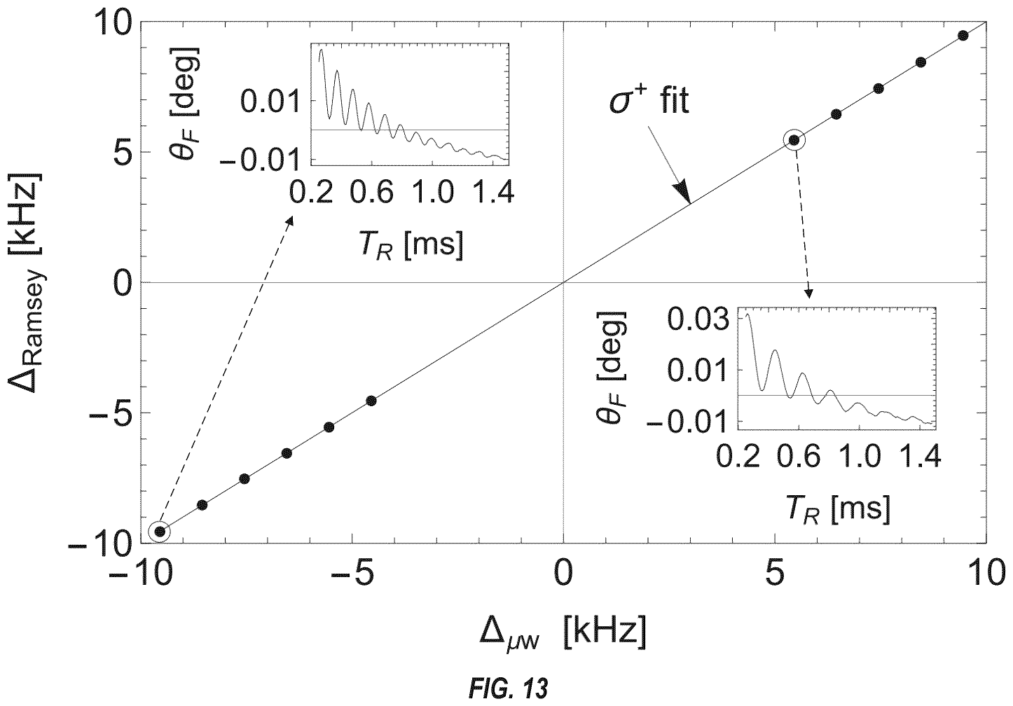

By varying the Ramsey free evolution time T_{R} between 0.2 ms and 1.43 ms at 10 μs spacing, Ramsey fringes may be measured at each microwave detuning as shown in the inset graphs of FIG. 13. FIG. 13 depicts Ramsey frequency vs microwave detuning for the σ⁺ transition. The Ramsey fringes may be fit using Equation (6), and the fringe frequencies Δ_{R} can be forced to be either positive or negative according to the sign of the microwave detuning

$${Δ}_{m}^{{m}^{′}} .$$

In some instances, ideally,

$${Δ}_{R} = {Δ}_{m}^{{m}^{′}} .$$

In one example, 6 microwave detunings

$${Δ}_{m}^{{m}^{′}} ∈ [ 5 , 10 ] kHz$$

may be chosen below and above each transition resonance as shown for the σ⁺ transition in FIG. 13. All of these measurements may be taken in random order to mitigate systematics from time-dependent drifts in the microwave field. By linear fitting AR as a function of the microwave frequency vₘᵤ, the π-intercept may measure

$${v}_{m}^{{m}^{′}} .$$

The magnetic field B may be obtained by fitting

$${v}_{m}^{{m}^{′}}$$

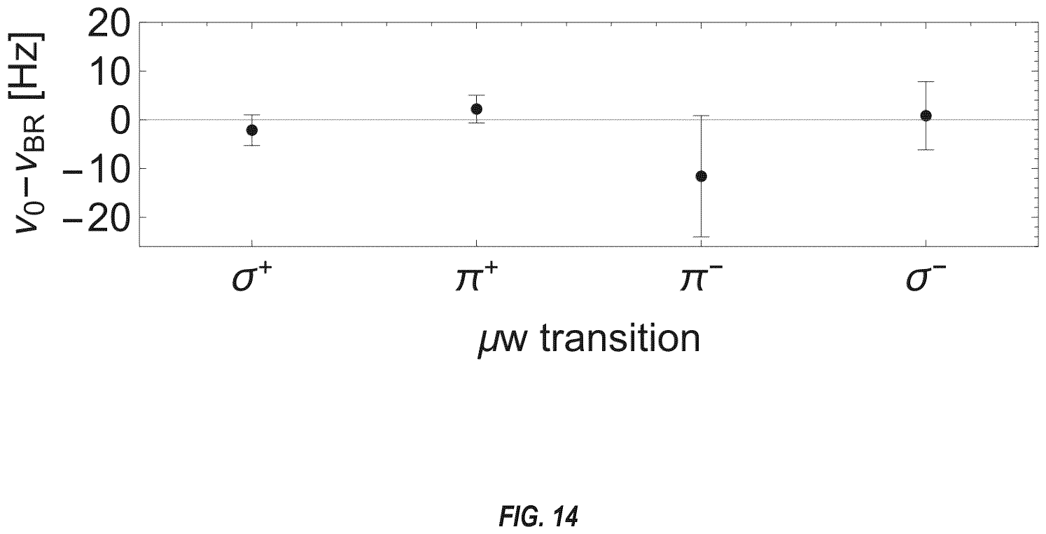

measurements to Equation (2). FIG. 14 depicts residuals of fitting the Breit-Rabi formula to the hyperfine resonances measured with Ramsey interferometry.

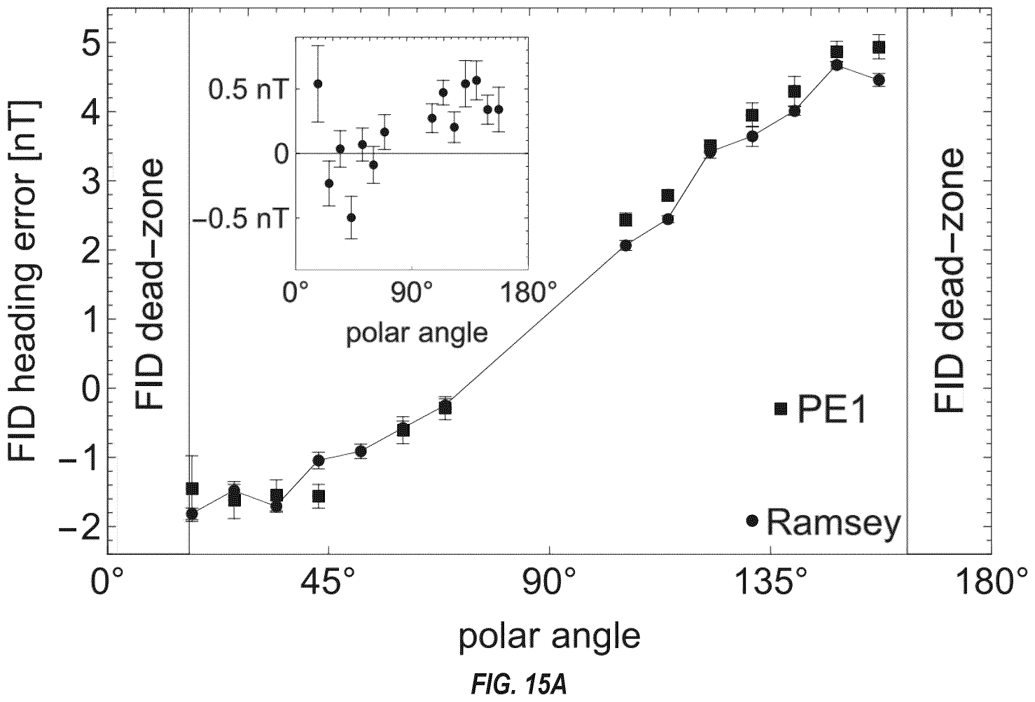

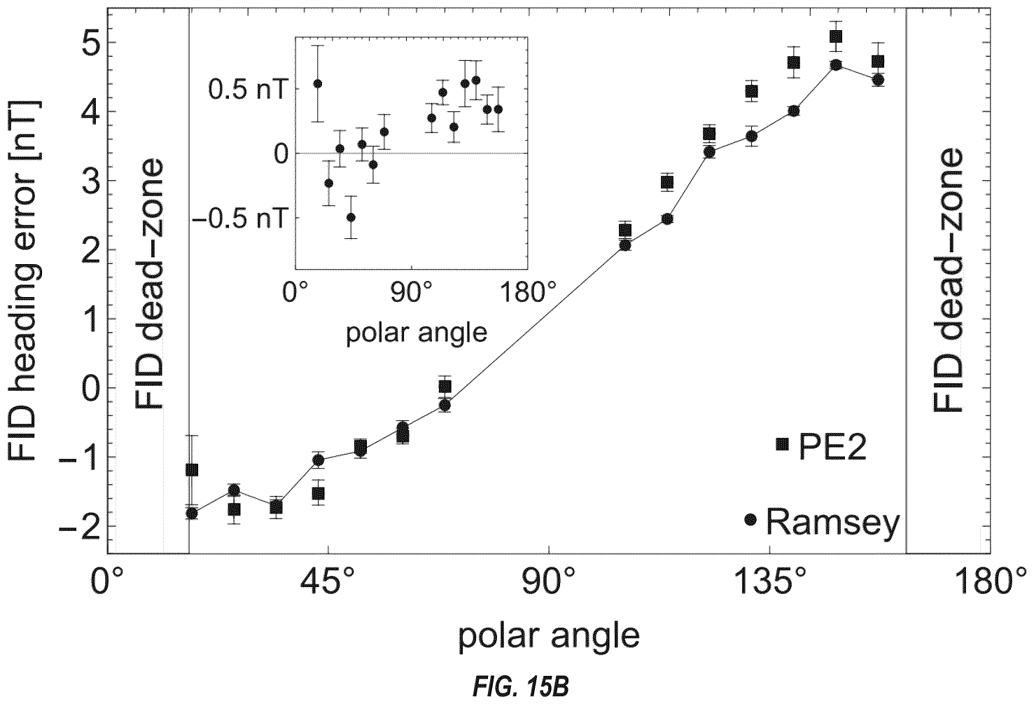

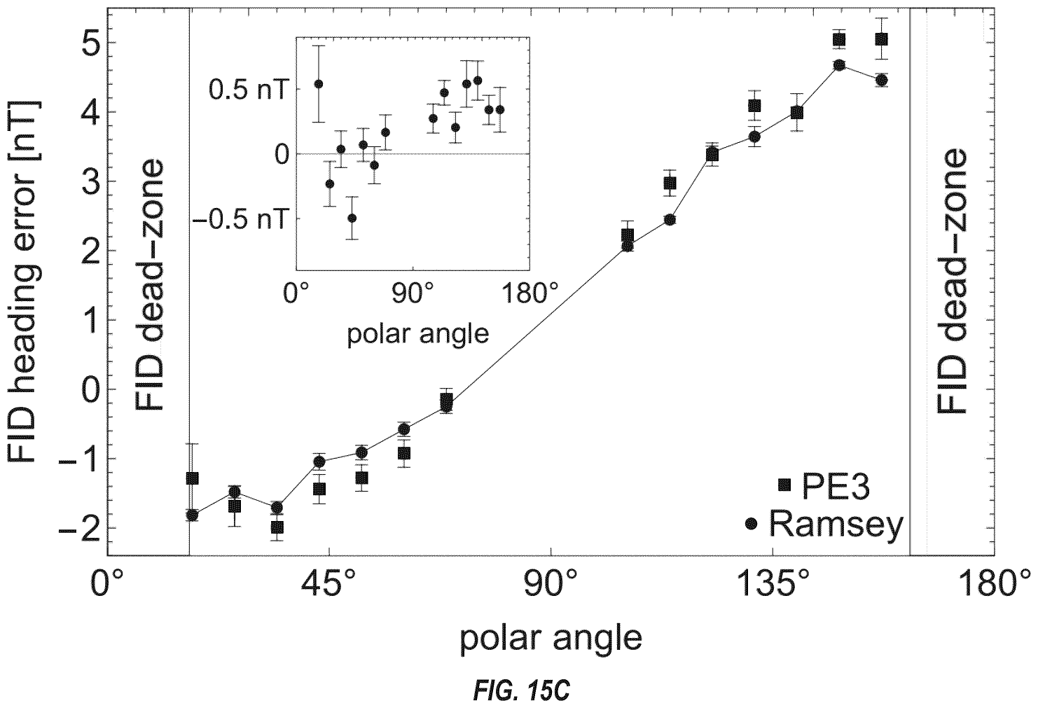

FIGS. 15A, 15B, and 15C depict a comparison of FSP heading errors measured by Rabi and Ramsey scalar magnetometry for 14 \vec{B} directions. For the example Rabi measurements shown in FIGS. 15A through 15C, only σ^{±} transitions were used since π⁺ can be more sensitive to frequency-shifts and can result in nT-scale discrepancies between different MPE evaluations. This observation is consistent with theoretical simulations that account for MPE frequency dependence, time-dependent MPE and pressure shift drifts, and lineshape distortions from atomic collisions. From these theoretical simulations, errors are estimated to be contained within 0.5 nT and 0.1 nT for the Rabi and Ramsey methods respectively. These estimates, along with drifts of the optical pumping parameters, are consistent with the measured differences, bounded by 0.6 nT, between the Ramsey and Rabi measurements averaged over the three MPEs (see insets of FIGS. 15A through 15C.

These results demonstrate how tailored atom-microwave coupling through Rabi and Ramsey spectroscopy can reduce OPM heading error to the sub-nT regime at geomagnetic fields. With these techniques, incorporating microwave sources into OPM packages can be utilized to correct heading errors in challenging domains such as the high buffer gas pressure environments utilized in microfabricated vapor cells and regimes of weak optical pumping. Moreover, these techniques can serve as calibration tools to create heading error look-up tables without explicitly being included in the OPM package.

### RF Rabi Vector Magnetometry

As disclosed herein, RF Rabi measurements within a 3D RF coil system can extract vector information and/or coil system information that can be used to correct drifts in real-time. Combined with coil modulations, RF Rabi measurements can enable full calibration of relevant parameters on the <100 ms timescale. RF Rabi measurements can obtain a large signal-to-noise ratio (SNR) with little RF power due to resonantly interacting with the atoms. This feature may enable improved vector sensitivity over coil modulation schemes.

An RF 3D coil system can be calibrated to accurately use, as an orthogonal coordinate system, (\vec{x}, \vec{y}, \vec{z}) for vector magnetometry. The coil system can comprise three near-orthogonal coil pairs that generate RF fields along coil directions (\vec{x}_{c}, \vec{y}_{c}, \vec{z}_{c}) (as depicted in FIG. 2) given in terms of RF coil currents

$${I}_{x} ( t ) = {I}_{x} cos ( {ω}_{RF} t + {ϕ}_{x} ) \qquad ( 8 )$$

$${I}_{y} ( t ) = {I}_{y} cos ( {ω}_{RF} t + {ϕ}_{y} ) \qquad ( 9 )$$

$${I}_{z} ( t ) = {I}_{z} cos ( {ω}_{RF} t ) \qquad ( 10 )$$

where without loss of generality ϕ_{z}=0 can be implemented. These currents may be written in a rotating-frame, enabling omission of the fast-rotating terms oscillating at 2ω_{RF}.

$${\tilde{I}}_{x} = {I}_{x} {e}^{i {ϕ}_{x}} \qquad ( 11 )$$

$${\tilde{I}}_{y} = {I}_{y} {e}^{i {ϕ}_{y}} \qquad ( 12 )$$

$${\tilde{I}}_{z} = {I}_{z} \qquad ( 13 )$$

The corresponding RF field components [symbol] _{k,c} along each coil pair can be defined as

$${x , c}_{} = {\tilde{I}}_{x} {a}_{x} {\vec{x}}_{c} \qquad ( 14 )$$

$${y , c}_{} = {\tilde{I}}_{y} {a}_{y} {\vec{y}}_{c} \qquad ( 15 )$$

$${z , c}_{} = {\tilde{I}}_{z} {a}_{z} {\vec{z}}_{c} \qquad ( 16 )$$

Here (aₓ, a_{y}, a_{z}) are coil coefficents to be determined. This coil frame may be defined in terms of non-orthogonality angles (δθₓ, δθ_{y}δϕ_{y}) given by

$${\vec{x}}_{c} = {R}_{y} ( π / 2 + δ {θ}_{x} ) \hat{z} = \{ cos [ δ {θ}_{x} ] , 0 , - sin [ δ {θ}_{x} ] \} \qquad ( 17 )$$

$${\vec{y}}_{c} = {R}_{z} ( π / 2 + δ {ϕ}_{y} ) {R}_{y} ( π / 2 + {δθ}_{y} ) \hat{z} = \{ - cos [ δ {θ}_{y} ] sin [ δ {ϕ}_{y} ] , cos [ δ {θ}_{y} ] cos [ {ϕ}_{y} ] , - sin [ δ {θ}_{y} ] \} \qquad ( 18 )$$

$${\vec{z}}_{c} = \hat{z} = \{ 0 , 0 , 1 \} \qquad ( 19 )$$

The total RF field written in the orthogonal coordinate system ( [symbol] ₂, [symbol] _{y}, [symbol] _{z}) may be given by

$$\vec{ℬ} = \{ {\sum }_{k = x , y , z} {\vec{B}}_{k , c} \cdot \hat{x} , {\sum }_{k = x , y , z} {\vec{B}}_{k , c} \cdot \hat{y} , {\sum }_{k = x , y , z} {\vec{B}}_{k , c} \cdot \hat{z} \} \qquad ( 20 )$$

It may be assumed that there is a DC magnetic field \vec{B} that points in the (α, β) direction in the (\vec{x}, \vec{y}, \vec{z}) orthogonal coordinate system. (α, β) may be determined using the frequencies of Rabi oscillations and RF polarization ellipses associated with the RF field. For convenience the RF field may be written such that 2 is parallel to \vec{B}.

$${α , β}^{} = {R}_{y} ( - β ) {R}_{z} ( - α ) \qquad ( 21 )$$

where R_{y} and R_{z} are rotation matrices about the y and 2 directions respectively. This new rotated coordinate frame may be denoted as (\vec{x}ᵣ, \vec{y}ᵣ, \vec{z}ᵣ). Complex spherical basis vectors in this rotated frame may be defined as

$${\hat{e}}_{+} = - \{ 1 , i , 0 \} / \sqrt{2} \qquad ( 22 )$$

$${\hat{e}}_{-} = \{ 1 , - i , 0 \} / \sqrt{2} \qquad ( 23 )$$

$${\hat{e}}_{π} = \{ 0 , 0 , 1 \} \qquad ( 24 )$$

The Rabi rates driven by the RF field [symbol] in the F=2 and F=1 hyperfine manifolds may be given by

$${Ω}_{+} \approx {μ}_{B} {g}_{F = 2} \vert {α , β}^{} \cdot {\hat{e}}_{+} \vert \qquad ( 25 )$$

$${Ω}_{-} \approx {μ}_{B} {g}_{F = 1} \vert {α , β}^{} \cdot {\hat{e}}_{-} \vert \qquad ( 26 )$$

where μ_{B} is the Bohr magneton and g_{f} is the hyperfine Lande g-factor. These expressions are approximate because they do not take into account non-linear Zeeman contributions and beyond rotating-wave effects. These effects can be accurately modeled and implemented, as understood by those of ordinary skill in the art and in view of the present disclosure, but are not detailed here.

Within this example model there are 10 unknown parameters, namely 3 coil coefficients (aₓ, a_{y}, a_{z}), 3 nonorthogonality angles (δθₓ, δθ_{y}, δϕ_{y}), 2 relative phases (ϕₓ, ϕ_{y}), and the DC magnetic field direction (α, β). Using RF Rabi measurements combined with low-frequency coil modulations of the RF coil system, all of these parameters may be extracted, though not with RF Rabi measurements alone. In one example, the parameters (α, β, δθₓ, δθ_{y}, δϕ_{y}) or (α, β, aₓ, a_{y}, a_{z}) are extracted, leaving at least 11 RF Rabi rates to be measured (+ and/or −) for random known RF currents (Iₓ, I_{y}, I_{z}). In another example, the parameters (α, β, δθₓ, δθ_{y}, δϕ_{y}, ϕₓ, ϕ_{y}) or (α, β, aₓ, a_{y}, a_{z}, ϕₓ, ϕ_{y}) are extracted, leaving at least 5 RF Rabi rates of each + and − to be measured for random known RF currents (Iₓ, I_{y}, I_{z}). In yet another example, all parameters (α, β, δθₓ, δθ_{y}, δϕ_{y}, ϕₓ, ϕ_{y}, aₓ, a_{y}, a_{z}) are extracted, which may be possible with RF rates and low-frequency coil modulations of the RF coil system.

In some implementations, the polarization ellipse may be given as

$${{\to }^{}}_{RF} = \frac{1}{2} {\sum }_{j ∈ \{ x , y , z \}} {j}_{} {e}^{- i ( {ϕ}_{j} + ω t )} + c . c \qquad ( 27 )$$

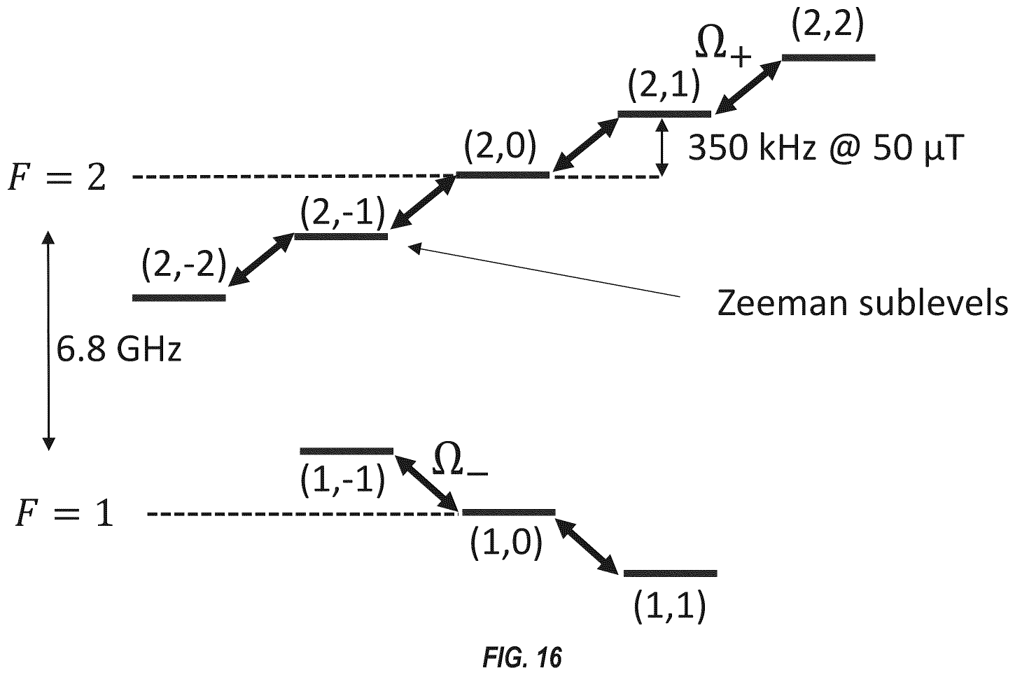

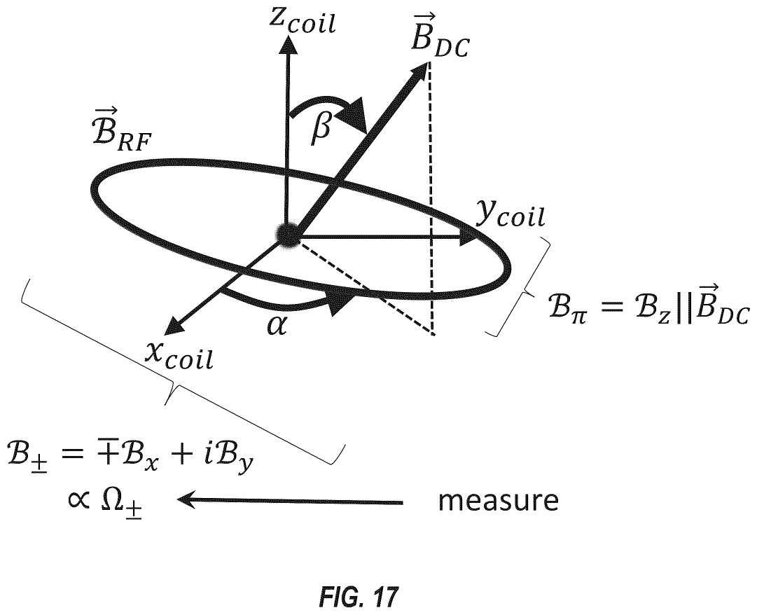

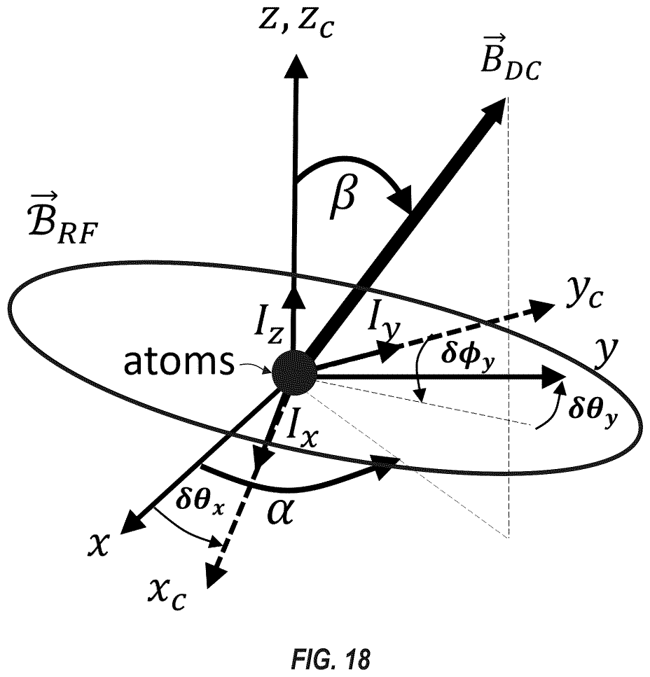

Leading to 5 PE (polarization ellipse) parameters: [symbol] ₓ, [symbol] _{y}, [symbol] _{z}, ϕₓ, ϕ_{y}(ϕ_{z}=0). FIG. 16 illustrates hyperfine ground states for Rb 87, wherein spherical RF components may drive Rabi oscillations. FIG. 17 illustrates a conceptual representation of spherical RF components determined by a DC magnetic field. FIG. 18 illustrates another conceptual representation of spherical RF components with non-orthogonal axes. As depicted in FIG. 18, the 3D RF coil system can define non-orthogonal axes (\vec{x}_{c}, \vec{y}_{c}, \vec{z}_{c}), where angles (δθₓ, δθ_{y}, δϕ_{y}) quantify non-orthogonality. Programmable RF currents with amplitudes (Iₓ, I_{y}, I_{z}) generate RF fields, which may be represented by

$${x , c}_{} ( t ) = {I}_{x} {a}_{x} cos ( {ω}_{RF} t + {ϕ}_{x 0} ) \qquad ( 28 )$$

$${y , c}_{} ( t ) = {I}_{y} {a}_{y} cos ( {ω}_{RF} t + {ϕ}_{y 0} ) \qquad ( 29 )$$

$${z , c}_{} ( t ) = {I}_{z} {a}_{z} cos ( {ω}_{RF} t ) \qquad ( 30 )$$

For different RF current settings, [symbol] ₊∝Ω₊ (F=2 manifold) may be measured, or [symbol] ₋ ∝Ω₋ (F=1 manifold) may be measured, or both may be measured. When either Ω₊ or Ω₋ is exclusively measured, (α, β, δθ_{y}, δθ_{y}, δϕ_{y}) or (α, β, aₓ, a_{y}, a_{z}) may be extracted. When both Ω₊ and Ω₋ are measured, (α, β, δθₓ, δθ_{y}, δϕ_{y}, ϕₓ₀, ϕ_{y0}) or (α, β, aₓ, a_{y}, a_{z}, ϕₓ₀, ϕ_{y0}) may be extracted. Although, in some instances, RF Rabi measurements alone cannot extract all parameters, the remaining parameters/unknowns (to obtain the full set of parameters (α, β, δθₓ, δθₓ, ϕₓ, ϕ_{y}, aₓ, a_{y}, a_{z}) may be obtained via coil modulation techniques implementing known RF currents, thereby enabling accurate magnetic field vector determination without rotating the DC field and/or the sensor.

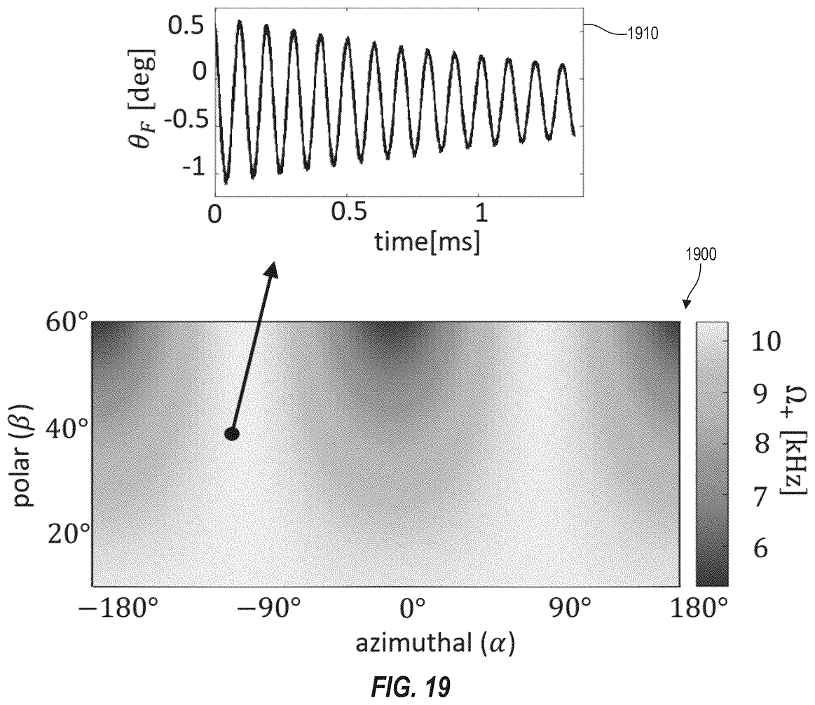

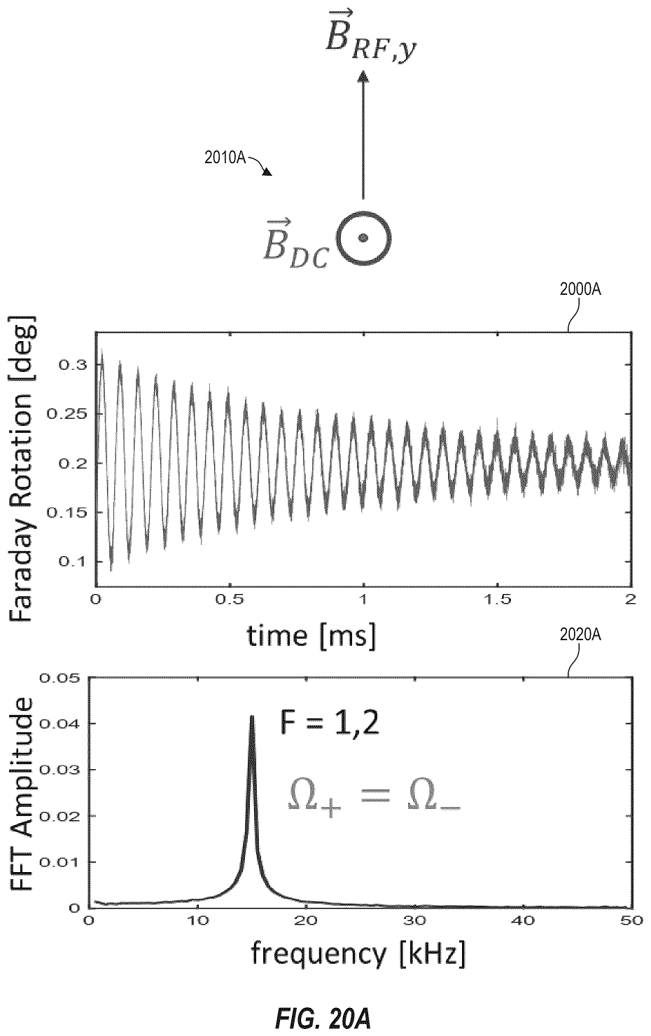

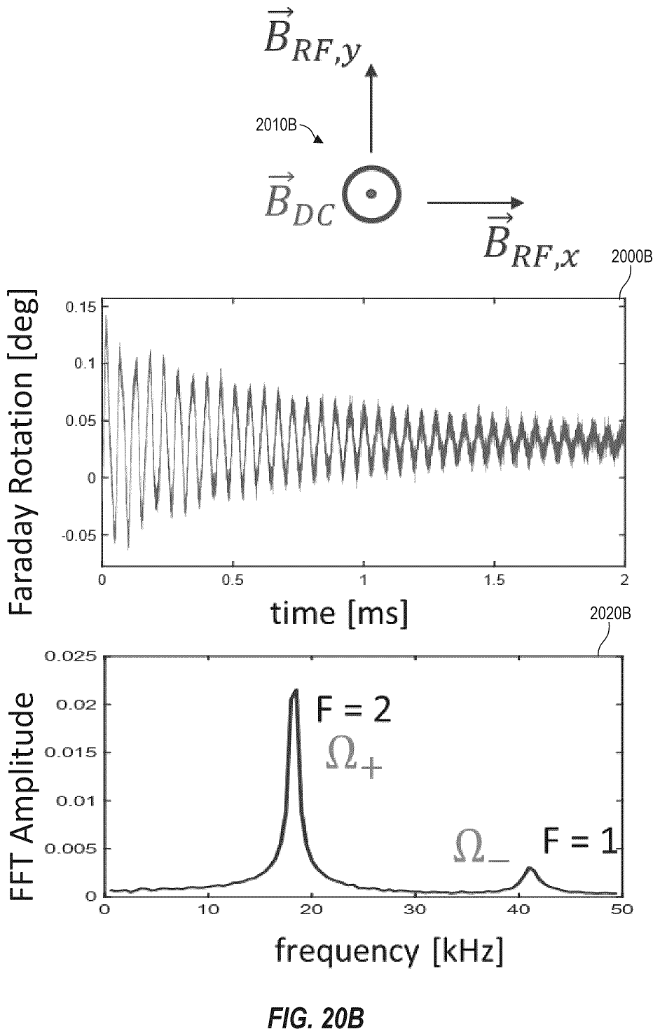

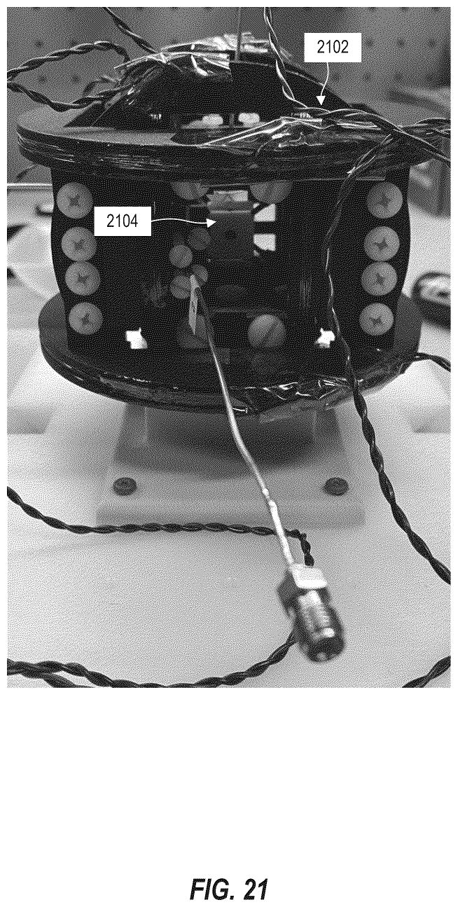

FIG. 19 depicts a heat map 1900 of measured RF Rabi frequency as a function of magnetic field direction using a single RF coil, as well as a graph 1910 of measured RF Rabi oscillation with single coil excitation for a particular RF Rabi frequency and magnetic field direction from the heat map. FIGS. 20A and 20B depict additional graphs 2000A and 2000B showing Rabi oscillations for magnetic fields 2010A and 2010B and Rabi frequencies represented in graphs 2020A and 2020B, respectively. FIG. 21 illustrates an example 3D RF coil system 2102 positioned about a microfabricated vapor cell 2104, which may be used to implement various RF Rabi vector magnetometry principles disclosed herein.

### Example Method(s)

The following discussion now refers to a number of methods and method acts that may be performed. Although the method acts may be discussed in a certain order or illustrated in a flow chart as occurring in a particular order, no particular ordering is required unless specifically stated, or required because an act is dependent on another act being completed prior to the act being performed.

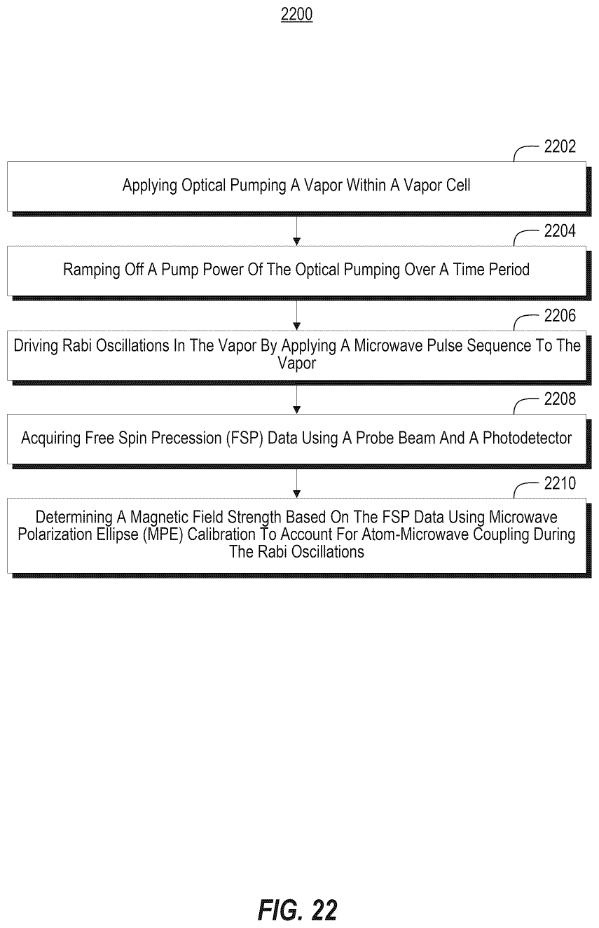

FIGS. 22, 23, and 24 illustrate example flow diagrams 2200, 2300, and 2400, respectively, depicting acts associated with the disclosed subject matter.

Act 2202 of flow diagram 2200 of FIG. 22 includes applying optical pumping a vapor within a vapor cell. In some instances, the vapor comprises an alkali atom vapor. In some implementations, the optical pumping of the vapor utilizes elliptically polarized pump light.

Act 2204 of flow diagram 2200 includes ramping off a pump power of the optical pumping over a time period. In some examples, ramping off of the pump power comprises linearly ramping off the pump power. In some embodiments, ramping off the pump power utilizes an adiabatic pump ramp. In some instances, the time period comprises about 50 μs.

Act 2206 of flow diagram 2200 includes driving Rabi oscillations in the vapor by applying a microwave pulse sequence to the vapor. In some implementations, the microwave pulse sequence comprises a frequency of about 6.8 GHz. In some examples, the microwave pulse sequence drives Rabi oscillations between different hyperfine sublevels about multiple hyperfine transitions. In some embodiments, the microwave pulse sequence is applied over about 0.85 ms.

Act 2208 of flow diagram 2200 includes acquiring free spin precession (FSP) data using a probe beam and a photodetector. In some instances, the probe beam utilizes linearly polarized light.

Act 2210 of flow diagram 2200 includes determining a magnetic field strength based on the FSP data using microwave polarization ellipse (MPE) calibration to account for atom-microwave coupling during the Rabi oscillations.

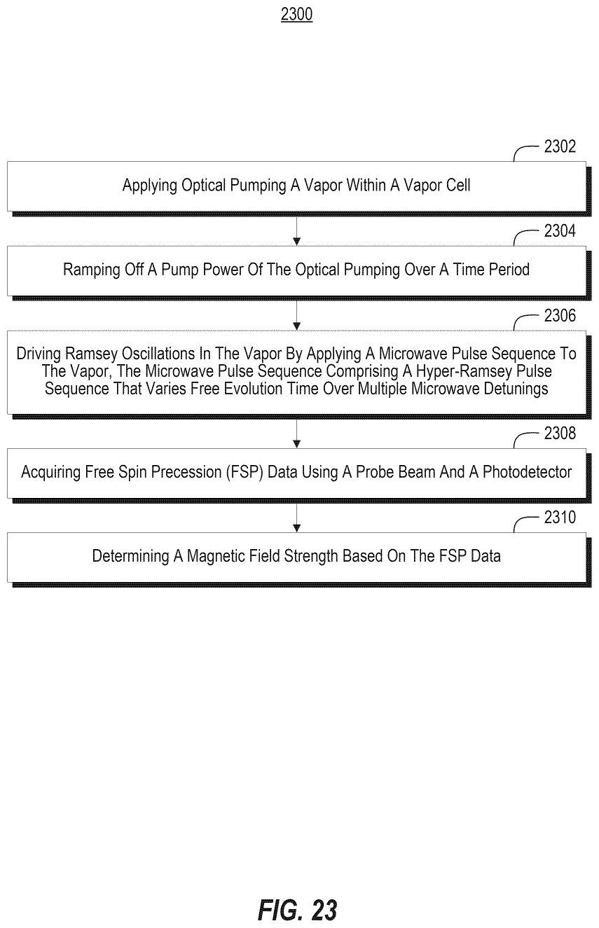

Act 2302 of flow diagram 2300 of FIG. 23 includes applying optical pumping a vapor within a vapor cell. In some implementations, the vapor comprises an alkali atom vapor. In some examples, the optical pumping of the vapor utilizes elliptically polarized pump light.

Act 2304 of flow diagram 2300 includes ramping off a pump power of the optical pumping over a time period. In some embodiments, ramping off of the pump power comprises linearly ramping off the pump power. In some instances, ramping off the pump power utilizes an adiabatic pump ramp. In some implementations, the time period comprises about 50 μs.

Act 2306 of flow diagram 2300 includes driving Ramsey oscillations in the vapor by applying a microwave pulse sequence to the vapor, the microwave pulse sequence comprising a hyper-Ramsey pulse sequence that varies free evolution time over multiple microwave detunings. In some examples, the microwave pulse sequence comprises a frequency of about 6.8 GHz. In some embodiments, the microwave pulse sequence comprises a hyper-Ramsey pulse sequence, where represents the free evolution time.

Act 2308 of flow diagram 2300 includes acquiring free spin precession (FSP) data using a probe beam and a photodetector.

Act 2310 of flow diagram 2300 includes determining a magnetic field strength based on the FSP data.

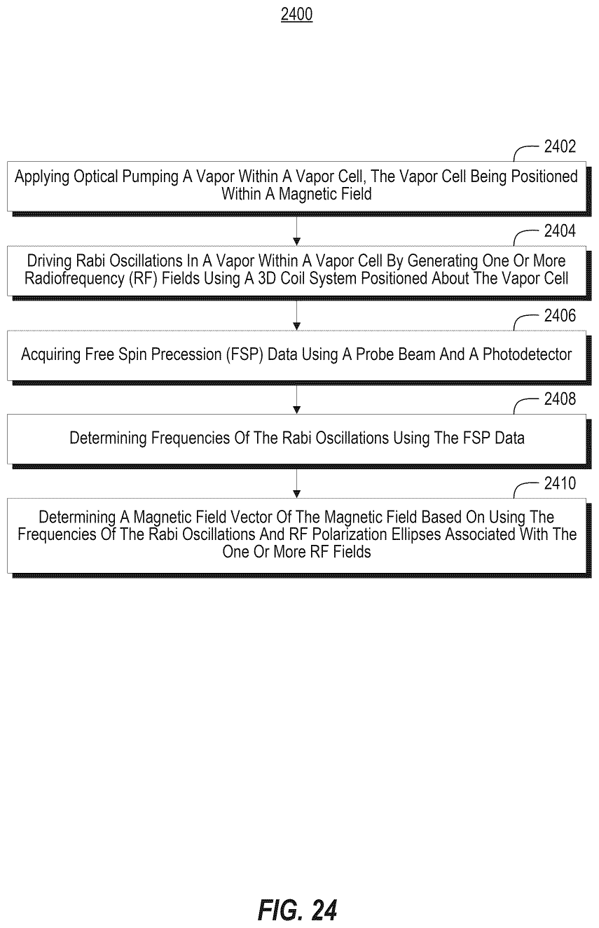

Act 2402 of flow diagram 2400 of FIG. 24 includes applying optical pumping a vapor within a vapor cell, the vapor cell being positioned within a magnetic field.

Act 2404 of flow diagram 2400 includes driving Rabi oscillations in a vapor within a vapor cell by generating one or more radiofrequency (RF) fields using a 3D coil system positioned about the vapor cell.

Act 2406 of flow diagram 2400 includes acquiring free spin precession (FSP) data using a probe beam and a photodetector.

Act 2408 of flow diagram 2400 includes determining frequencies of the Rabi oscillations using the FSP data.

Act 2410 of flow diagram 2400 includes determining a magnetic field vector of the magnetic field based on using the frequencies of the Rabi oscillations and RF polarization ellipses associated with the one or more RF fields. In some instances, the RF polarization ellipses are calibrated by varying RF strength in different coil pairs of the 3D coil system.

Embodiments disclosed herein can include those in the following numbered clauses:

Clause 1. A method for atomic scalar magnetometry, comprising: applying optical pumping to a vapor within a vapor cell; ramping off a pump power of the optical pumping over a time period; driving Rabi oscillations in the vapor by applying a microwave pulse sequence to the vapor; and determining a magnetic field strength by measuring frequency of the Rabi oscillations.

Clause 2. The method of clause 1, wherein the vapor comprises an atom vapor.

Clause 3. The method of clause 1, wherein the optical pumping of the vapor utilizes elliptically polarized pump light.

Clause 4. The method of clause 1, wherein ramping off of the pump power comprises monotonically ramping off the pump power.

Clause 5. The method of clause 1, wherein ramping off the pump power utilizes an adiabatic pump ramp.

Clause 6. The method of clause 1, wherein a signal indicating the frequency of the Rabi oscillations is obtained using a probe beam.

Clause 7. The method of clause 6, wherein the probe beam utilizes near-linearly polarized light.

Clause 8. The method of clause 6, wherein the optical pumping and the probe beam are achieved with collinear laser light.

Clause 9. The method of clause 6, wherein the optical pumping and the probe beam are achieved with a same laser.

Clause 10. The method of clause 1, wherein the microwave pulse sequence drives the Rabi oscillations between different hyperfine sublevels about multiple hyperfine transitions.

Clause 11. A method for atomic scalar magnetometry, comprising: applying optical pumping to a vapor within a vapor cell; ramping off a pump power of the optical pumping over a time period; driving Ramsey oscillations in the vapor by applying a microwave pulse sequence to the vapor; and determining a magnetic field strength based on a signal derived from the Ramsey oscillations.

Clause 12. The method of clause 11, wherein the vapor comprises an alkali atom vapor.

Clause 13. The method of clause 11, wherein the optical pumping of the vapor utilizes elliptically polarized pump light.

Clause 14. The method of clause 11, wherein ramping off of the pump power comprises linearly ramping off the pump power.

Clause 15. The method of clause 11, wherein ramping off the pump power utilizes an adiabatic pump ramp.

Clause 16. The method of clause 11, wherein the Ramsey oscillations are measured using a probe beam.

Clause 17. The method of clause 16, wherein the optical pumping and the probe beam are achieved with collinear light beams.

Clause 18. The method of clause 11, wherein the microwave pulse sequence comprises a hyper-Ramsey pulse sequence, where represents free evolution time.

Clause 19. A method for atomic vector magnetometry, comprising: applying optical pumping to a vapor within a vapor cell, the vapor cell being positioned within a magnetic field; driving Rabi oscillations in the vapor within the vapor cell by generating one or more radiofrequency (RF) fields using a 3D coil system positioned about the vapor cell; and determining a magnetic field vector of the magnetic field based on frequencies of the Rabi oscillations.

Clause 20. The method of clause 19, wherein the Rabi oscillations are driven between Zeeman levels.

### Additional Details Related to Implementing the Disclosed Embodiments

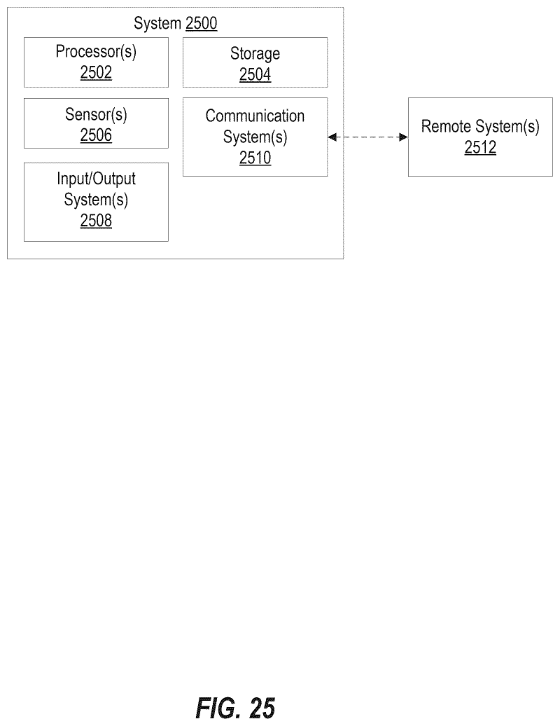

FIG. 25 illustrates example components of a system 2500 that may comprise or implement aspects of one or more disclosed embodiments. For example, FIG. 25 illustrates an implementation in which the system 2500 includes processor(s) 2502, storage 2504, sensor(s) 2506, I/O system(s) 2508, and communication system(s) 2510. Although FIG. 25 illustrates a system 2500 as including particular components, one will appreciate, in view of the present disclosure, that a system 2500 may comprise any number of additional or alternative components.

The processor(s) 2502 may comprise one or more sets of electronic circuitries that include any number of logic units, registers, and/or control units to facilitate the execution of computer-readable instructions (e.g., instructions that form a computer program). Such computer-readable instructions may be stored within storage 2504. The storage 2504 may comprise physical system memory or computer-readable recording media and may be volatile, non-volatile, or some combination thereof. Furthermore, storage 2504 may comprise local storage, remote storage (e.g., accessible via communication system(s) 2510 or otherwise), or some combination thereof. Additional details related to processors (e.g., processor(s) 2502) and computer storage media (e.g., storage 2504) will be provided hereinafter.

As will be described in more detail, the processor(s) 2502 may be configured to execute instructions stored within storage 2504 to perform certain actions. In some instances, the actions may rely at least in part on communication system(s) 2510 for receiving data from remote system(s) 2512, which may include, for example, separate systems or computing devices, sensors, and/or others. The communications system(s) 2510 may comprise any combination of software or hardware components that are operable to facilitate communication between on-system components/devices and/or with off-system components/devices. For example, the communications system(s) 2510 may comprise ports, buses, or other physical connection apparatuses for communicating with other devices/components. Additionally, or alternatively, the communications system(s) 2510 may comprise systems/components operable to communicate wirelessly with external systems and/or devices through any suitable communication channel(s), such as, by way of non-limiting example, Bluetooth, ultra-wideband, WLAN, infrared communication, and/or others.

FIG. 25 illustrates that a system 2500 may comprise or be in communication with sensor(s) 2506. Sensor(s) 2506 may comprise any device for capturing or measuring data representative of perceivable phenomenon. By way of non-limiting example, the sensor(s) 2506 may comprise one or more antennae, monopoles, image sensors, microphones, thermometers, barometers, magnetometers, accelerometers, gyroscopes, and/or others.

Furthermore, FIG. 25 illustrates that a system 2500 may comprise or be in communication with I/O system(s) 2508. I/O system(s) 2508 may include any type of input or output device such as, by way of non-limiting example, a display, a touch screen, a mouse, a keyboard, a controller, and/or others, without limitation.

Disclosed embodiments may comprise or utilize a special purpose or general-purpose computer including computer hardware, as discussed in greater detail below. Disclosed embodiments also include physical and other computer-readable media for carrying or storing computer-executable instructions and/or data structures. Such computer-readable media can be any available media that can be accessed by a general-purpose or special-purpose computer system. Computer-readable media that store computer-executable instructions in the form of data are one or more “physical computer storage media” or “hardware storage device(s).” Computer-readable media that merely carry computer-executable instructions without storing the computer-executable instructions are “transmission media.” Thus, by way of example and not limitation, the current embodiments can comprise at least two distinctly different kinds of computer-readable media: computer storage media and transmission media.

Computer storage media (aka “hardware storage device”) are computer-readable recording media, such as RAM, ROM, EEPROM, CD-ROM, solid state drives (“SSD”) that are based on RAM, Flash memory, phase-change memory (“PCM”), or other types of memory, or other optical disk storage, magnetic disk storage or other magnetic storage devices, or any other medium that can be used to store desired program code means in hardware in the form of computer-executable instructions, data, or data structures and that can be accessed by a general-purpose or special-purpose computer.

A “network” is defined as one or more data links that enable the transport of electronic data between computer systems and/or modules and/or other electronic devices. When information is transferred or provided over a network or another communications connection (either hardwired, wireless, or a combination of hardwired or wireless) to a computer, the computer properly views the connection as a transmission medium. Transmission media can include a network and/or data links which can be used to carry program code in the form of computer-executable instructions or data structures and which can be accessed by a general purpose or special purpose computer. Combinations of the above are also included within the scope of computer-readable media.

Further, upon reaching various computer system components, program code means in the form of computer-executable instructions or data structures can be transferred automatically from transmission computer-readable media to physical computer-readable storage media (or vice versa). For example, computer-executable instructions or data structures received over a network or data link can be buffered in RAM within a network interface module (e.g., a “NIC”), and then eventually transferred to computer system RAM and/or to less volatile computer-readable physical storage media at a computer system. Thus, computer-readable physical storage media can be included in computer system components that also (or even primarily) utilize transmission media.

Computer-executable instructions comprise, for example, instructions and data which cause a general-purpose computer, special purpose computer, or special purpose processing device to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

Disclosed embodiments may comprise or utilize cloud computing. A cloud model can be composed of various characteristics (e.g., on-demand self-service, broad network access, resource pooling, rapid elasticity, measured service, etc.), service models (e.g., Software as a Service (“SaaS”), Platform as a Service (“PaaS”), Infrastructure as a Service (“IaaS”), and deployment models (e.g., private cloud, community cloud, public cloud, hybrid cloud, etc.).

Those skilled in the art will appreciate that at least some aspects of the invention may be practiced in network computing environments with many types of computer system configurations, including, personal computers, desktop computers, laptop computers, message processors, hand-held devices, multi-processor systems, microprocessor-based or programmable consumer electronics, network PCs, minicomputers, mainframe computers, mobile telephones, PDAs, pagers, routers, switches, wearable devices, and the like. The invention may also be practiced in distributed system environments where multiple computer systems (e.g., local and remote systems), which are linked through a network (either by hardwired data links, wireless data links, or by a combination of hardwired and wireless data links), perform tasks. In a distributed system environment, program modules may be located in local and/or remote memory storage devices.

Alternatively, or in addition, at least some of the functionality described herein can be performed, at least in part, by one or more hardware logic components. For example, and without limitation, illustrative types of hardware logic components that can be used include Field-programmable Gate Arrays (FPGAs), Program-specific Integrated Circuits (ASICs), Application-specific Standard Products (ASSPs), System-on-a-chip systems (SOCs), Complex Programmable Logic Devices (CPLDs), central processing units (CPUs), graphics processing units (GPUs), and/or others.

As used herein, the terms “executable module,” “executable component,” “component,” “module,” or “engine” can refer to hardware processing units or to software objects, routines, or methods that may be executed on one or more computer systems. The different components, modules, engines, and services described herein may be implemented as objects or processors that execute on one or more computer systems (e.g., as separate threads).

One will also appreciate how any feature or operation disclosed herein may be combined with any one or combination of the other features and operations disclosed herein. Additionally, the content or feature in any one of the figures may be combined or used in connection with any content or feature used in any of the other figures. In this regard, the content disclosed in any one figure is not mutually exclusive and instead may be combinable with the content from any of the other figures.

The present invention may be embodied in other specific forms without departing from its spirit or characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is currently claimed is:

1. A method for atomic scalar magnetometry, comprising:
applying optical pumping to a vapor within a vapor cell;
ramping off a pump power of the optical pumping over a time period;
driving Rabi oscillations in the vapor by applying a microwave pulse sequence to the vapor; and
determining a magnetic field strength by measuring frequency of the Rabi oscillations.

2. The method of claim 1, wherein the vapor comprises an atom vapor.

3. The method of claim 1, wherein the optical pumping of the vapor utilizes elliptically polarized pump light.

4. The method of claim 1, wherein ramping off of the pump power comprises monotonically ramping off the pump power.

5. The method of claim 1, wherein ramping off the pump power utilizes an adiabatic pump ramp.

6. The method of claim 1, wherein a signal indicating the frequency of the Rabi oscillations is obtained using a probe beam.

7. The method of claim 6, wherein the probe beam utilizes near-linearly polarized light.

8. The method of claim 6, wherein the optical pumping and the probe beam are achieved with collinear laser light.

9. The method of claim 6, wherein the optical pumping and the probe beam are achieved with a same laser.

10. The method of claim 1, wherein the microwave pulse sequence drives the Rabi oscillations between different hyperfine sublevels about multiple hyperfine transitions.

11. A method for atomic scalar magnetometry, comprising:
applying optical pumping to a vapor within a vapor cell;
ramping off a pump power of the optical pumping over a time period;
driving Ramsey oscillations in the vapor by applying a microwave pulse sequence to the vapor; and
determining a magnetic field strength based on a signal derived from the Ramsey oscillations.

12. The method of claim 11, wherein the vapor comprises an alkali atom vapor.

13. The method of claim 11, wherein the optical pumping of the vapor utilizes elliptically polarized pump light.

14. The method of claim 11, wherein ramping off of the pump power comprises linearly ramping off the pump power.

15. The method of claim 11, wherein ramping off the pump power utilizes an adiabatic pump ramp.

16. The method of claim 11, wherein the Ramsey oscillations are measured using a probe beam.

17. The method of claim 16, wherein the optical pumping and the probe beam are achieved with collinear light beams.

18. The method of claim 11, wherein the microwave pulse sequence comprises a π/2−T_{R}−3π/2 hyper-Ramsey pulse sequence, where T_{R} represents free evolution time.

19. A method for atomic vector magnetometry, comprising:
applying optical pumping to a vapor within a vapor cell, the vapor cell being positioned within a magnetic field;
driving Rabi oscillations in the vapor within the vapor cell by generating one or more radiofrequency (RF) fields using a 3D coil system positioned about the vapor cell; and
determining a magnetic field vector of the magnetic field based on frequencies of the Rabi oscillations.

20. The method of claim 19, wherein the Rabi oscillations are driven between Zeeman levels.
